(19) United States
(12) Patent Application Publication
(10) Pub. No.: US 2024/0268147 A1
(43) Pub. Date: Aug. 8, 2024

(54) DISPLAY PANEL AND DISPLAY APPARATUS

(71) Applicant: BOE Technology Group Co., Ltd., Beijing (CN)

(72) Inventors: Hao Zhang, Beijing (CN); Liming Dong, Beijing (CN)

(73) Assignee: BOE Technology Group Co., Ltd., Beijing (CN)

(21) Appl. No.: 18/040,775

(22) PCT Filed: May 11, 2022
(86) PCT No.: PCT/CN2022/092120

§ 371 Date: Feb. 6, 2023

(51) Int. Cl. H10K 59/121; H10K 59/123; H10K 59/88

(52) U.S. Cl. CPC H10K 59/121; H10K 59/123; H10K 59/88

(57) ABSTRACT

A display panel is provided. The display panel includes light emitting elements and pixel driving circuits in a first region, and at least one of a second region or a third region at least partially spacing apart the first region and the second region. Configurations of light emitting elements in at least two of the first region, the second region, and the third region are different from each other. Configurations of pixel driving circuits in at least two of the first region, the second region, and the third region are different from each other.

### TECHNICAL FIELD

The present invention relates to display technology, more particularly, to a display panel and a display apparatus.

### BACKGROUND

Organic Light Emitting Diode (OLED) display is one of the hotspots in the field of flat panel display research today. Unlike Thin Film Transistor-Liquid Crystal Display (TFT-LCD), which uses a stable voltage to control brightness, OLED is driven by a driving current required to be kept constant to control illumination. The OLED display panel includes a plurality of pixel units configured with pixel-driving circuits arranged in multiple rows and columns. Each pixel-driving circuit includes a driving transistor having a gate terminal connected to one gate line per row and a drain terminal connected to one data line per column. When the row in which the pixel unit is gated is turned on, the switching transistor connected to the driving transistor is turned on, and the data voltage is applied from the data line to the driving transistor via the switching transistor, so that the driving transistor outputs a current corresponding to the data voltage to an OLED device. The OLED device is driven to emit light of a corresponding brightness.

### SUMMARY

In one aspect, the present disclosure provides a display panel, comprising light emitting elements and pixel driving circuits in a first region and at least one of a second region or a third region, the third region, when present, at least partially spacing apart the first region and the second region; configurations of light emitting elements in at least two of the first region, the second region, and the third region are different from each other; and configurations of pixel driving circuits in at least two of the first region, the second region, and the third region are different from each other.

Optionally, the display panel comprises a plurality of first light emitting elements in the first region, a plurality of second light emitting elements in the second region, and a plurality of third light emitting elements in the third region; light emitting elements in at least two of the first region, the second region, and the third region have different sizes, arrangements, and light emitting apertures.

Optionally, the display panel comprises a plurality of first pixels in the first region, a plurality of second pixels in the second region, and a plurality of third pixels in the third region; pixels in at least two of the first region, the second region, and the third region have different sizes, arrangements, and resolutions; and a first pixel size of the plurality of first pixels is greater than a second pixel size of the plurality of second pixels.

Optionally, the plurality of first pixels in the first region are arranged in an array comprising rows and columns; and the plurality of second pixels in the second region are arranged along a plurality of second arcs curving toward a same direction.

Optionally, the plurality of second arcs along which the plurality of second pixels in the second region are arranged are concentric.

Optionally, the plurality of first pixels has a first pixel-per-inch value; the plurality of second pixels has a second pixel-per-inch value; and the first pixel-per-inch value is greater than the second pixel-per-inch value.

Optionally, light emitting elements of a same color in the second region are arranged along a plurality of first arcs curving toward a same direction; and the display panel includes a plurality of second pixels in the second region arranged along a plurality of second arcs curving toward a same direction.

Optionally, the plurality of first arcs are concentric, and the plurality of second arcs are concentric.

Optionally, the second region comprises a plurality of via holes at least partially extending into the display panel.

Optionally, the plurality of via holes are arranged along a plurality of third arcs curved toward a same direction.

Optionally, the plurality of third arcs are concentric.

Optionally, an individual via hole of the plurality of via holes has a cross shape comprising a first line and a second line intersecting each other; and first lines of cross shapes of the plurality of via holes are oriented toward a same center.

Optionally, light emitting elements of a same color in the second region are arranged along a plurality of first arcs curving toward a same direction; a respective first arc of the plurality of first arcs is between two adjacent third arcs of the plurality of third arcs; and a respective third arc of the plurality of third arcs is between two adjacent first arcs of the plurality of first arcs.

Optionally, the display panel comprises a respective second light emitting element in the second region, and a respective second pixel driving circuit configured to drive light emission in the respective second light emitting element; wherein the respective second pixel driving circuit is in the third region or in the first region.

Optionally, the display panel comprises a scan circuit having a plurality of stages, and configured to provide control signals to different rows of subpixels; a respective scan unit of the scan circuit is at least partially in the third region, and is configured to provide scan signals to subpixels in the second region and subpixels in the first region; the display panel comprises a respective first output line and a respective second output line connected to the respective scan unit; the respective first output line is configured to transmit control signals from the respective scan unit to a row of subpixels in the first region; and the respective second output line is configured to transmit control signals from the respective scan unit to a row of subpixels in the third region.

Optionally, the display panel comprises plurality of second data lines configured to provide data signals to subpixels in the second region; portions of the plurality of second data lines in the second region extend along a plurality of fourth arcs, respectively; and the plurality of fourth arcs curve toward a same direction.

Optionally, the display panel comprises a main signal line and a plurality of branch signal lines connected to the main signal line, the main signal line and the plurality of branch signal lines configured to provide signals to the subpixels in the second region; the plurality of branch signal lines form an interconnected signal line network in the second region; and the main signal line is outside the second region.

Optionally, the display panel is a curved display panel having a three-dimensional body; the first region comprises at least a main display region of the display panel; the second region is at least partially in a corner portion of the three-dimensional body.

Optionally, the first region includes a first sub-region, a second sub-region, and a third sub-region; the first sub-region is at least partially in a top portion of the three-dimensional body; the second sub-region is at least partially in a first edge portion of the three-dimensional body; the third sub-region is at least partially in a second edge portion of the three-dimensional body; and the third region at least partially spaces apart the first region and the second region.

In another aspect, the present disclosure provides a display apparatus, comprising the display panel described herein or fabricated by a method described herein, and one or more integrated circuit connected to the display panel.

### BRIEF DESCRIPTION OF THE FIGURES

The following drawings are merely examples for illustrative purposes according to various disclosed embodiments and are not intended to limit the scope of the present invention.

FIG. 1 is a schematic diagram of a display panel in some embodiments according to the present disclosure.

FIG. 2 is a circuit diagram illustrating the structure of a respective pixel driving circuit and a respective light emitting element in some embodiments according to the present disclosure.

FIG. 3 is a plan view of a display panel in some embodiments according to the present disclosure.

FIG. 4 is a perspective view of a display panel in some embodiments according to the present disclosure.

FIG. 5 is a zoom-in view of a corner portion of the display panel depicted in FIG. 4.

FIG. 6 is a schematic diagram of a display panel in some embodiments according to the present disclosure.

FIG. 7A illustrates configurations of components in a first region, a second region, and a third region of a display panel in some embodiments according to the present disclosure.

FIG. 7B illustrates the layout of a plurality of first arcs in a display panel in some embodiments according to the present disclosure.

FIG. 7C illustrates the layout of a plurality of second arcs in a display panel in some embodiments according to the present disclosure.

FIG. 7D illustrates the layout of a plurality of via holes in a display panel in some embodiments according to the present disclosure.

FIG. 7E illustrates the layout of a plurality of via holes in a display panel in some embodiments according to the present disclosure.

FIG. 8 illustrates configurations of components in a first region, a second region, and a third region of a display panel in some embodiments according to the present disclosure.

FIG. 9A illustrates the structure of a respective second pixel driving circuit and a respective second light emitting element in some embodiments according to the present disclosure.

FIG. 9B illustrates the structure of a semiconductor material layer in a display panel depicted in FIG. 9A.

FIG. 9C illustrates the structure of a first conductive layer in a display panel depicted in FIG. 9A.

FIG. 9D illustrates the structure of an insulating layer in a display panel depicted in FIG. 9A.

FIG. 9E illustrates the structure of a second conductive layer in a display panel depicted in FIG. 9A.

FIG. 9F illustrates the structure of a first signal layer in a display panel depicted in FIG. 9A.

FIG. 9G illustrates the structure of a second signal layer in a display panel depicted in FIG. 9A.

FIG. 9H illustrates the structure of a third signal layer in a display panel depicted in FIG. 9A.

FIG. 9I illustrates the structure of an anode layer in a display panel depicted in FIG. 9A.

FIG. 9J illustrates the structure of a pixel definition layer in a display panel depicted in FIG. 9A.

FIG. 9K illustrates the structure of a light emitting layer in a display panel depicted in FIG. 9A.

FIG. 10A is a cross-sectional view along an A-A′ line in FIG. 9A.

FIG. 10B is a cross-sectional view along a B-B′ line in FIG. 9A.

FIG. 11 illustrates connection between a respective second pixel driving circuit and a respective second light emitting element in some embodiments according to the present disclosure.

FIG. 12A illustrates configurations of components in a first region, a second region, and a third region of a display panel in some embodiments according to the present disclosure.

FIG. 12B is a schematic diagram illustrating the structure of a scan circuit in a display panel in some embodiments according to the present disclosure.

FIG. 13 is a circuit diagram of a respective scan unit of a scan circuit in some embodiments according to the present disclosure.

FIG. 14A illustrates configurations of components in a first region, a second region, and a third region of a display panel in some embodiments according to the present disclosure.

FIG. 14B is a schematic diagram illustrating the layout of a plurality of data lines in a display panel in some embodiments according to the present disclosure.

FIG. 15 is a schematic diagram illustrating the layout of a plurality of data lines in a display panel in some embodiments according to the present disclosure.

FIG. 16A illustrates configurations of components in a first region, a second region, and a third region of a display panel in some embodiments according to the present disclosure.

FIG. 16B is a schematic diagram illustrating the layout of a plurality of data lines in a display panel in some embodiments according to the present disclosure.

FIG. 17A illustrates configurations of components in a first region, a second region, and a third region of a display panel in some embodiments according to the present disclosure.

FIG. 17B is a schematic diagram illustrating the layout of first voltage supply lines in a display panel in some embodiments according to the present disclosure.

FIG. 18A illustrates configurations of components in a first region, a second region, and a third region of a display panel in some embodiments according to the present disclosure.

FIG. 18B is a schematic diagram illustrating the layout of reset signal lines in a display panel in some embodiments according to the present disclosure.

FIG. 19A illustrates configurations of components in a first region, a second region, and a third region of a display panel in some embodiments according to the present disclosure.

FIG. 19B is a schematic diagram illustrating the layout of second voltage supply lines in a display panel in some embodiments according to the present disclosure.

### DETAILED DESCRIPTION

The disclosure will now be described more specifically with reference to the following embodiments. It is to be noted that the following descriptions of some embodiments are presented herein for purpose of illustration and description only. It is not intended to be exhaustive or to be limited to the precise form disclosed.

The present disclosure provides, inter alia, a display panel and a display apparatus that substantially obviate one or more of the problems due to limitations and disadvantages of the related art. In one aspect, the present disclosure provides a display panel. In some embodiments, the display panel includes light emitting elements and pixel driving circuits in a first region, and at least one of a second region or a third region at least partially spacing apart the first region and the second region. Optionally, configurations of light emitting elements in at least two of the first region, the second region, and the third region are different from each other. Optionally, configurations of pixel driving circuits in at least two of the first region, the second region, and the third region are different from each other.

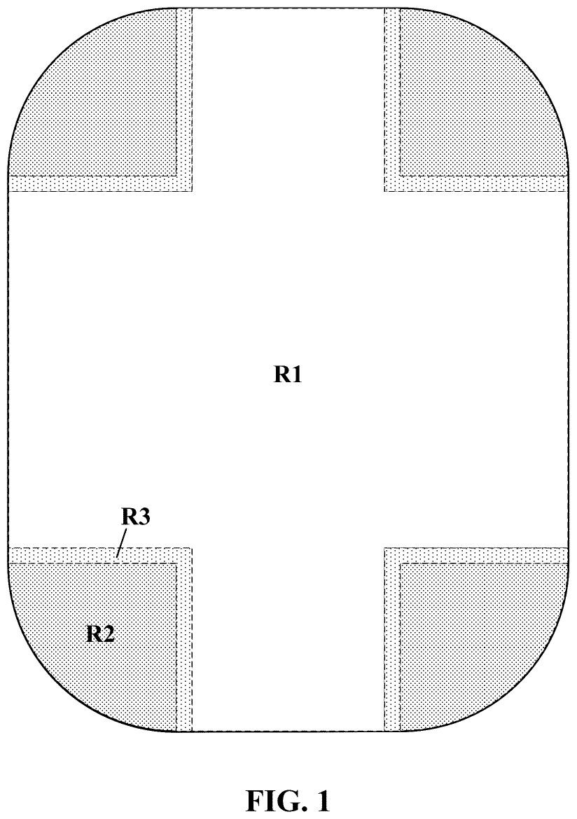

FIG. 1 is a schematic diagram of a display panel in some embodiments according to the present disclosure. Referring to FIG. 1, the display panel in some embodiments includes a first region R1 and a second region R2. Optionally, the display panel further includes a third region R3.

In some embodiments, the display panel includes light emitting elements. Optionally, configurations of light emitting elements in the first region R1 and in the second region R2 are different from each other. Optionally, configurations of light emitting elements in the first region R1 and in the third region R3 are different from each other. Optionally, configurations of light emitting elements in the second region R2 and in the third region R3 are different from each other. Optionally, configurations of light emitting elements in the first region R1, in the second region R2, and in the third region R3 are different from each other.

As used herein, the term “configuration” refers to at least one of arrangement of components (e.g., light emitting elements), shape of the components, size of the components, orientation of the components, inter-component distance (e.g., inter-light emitting element distance), distribution density of the components, alignment of the components, aperture ratio of the components, resolution (e.g., pixel per inch or PPI) of the components, light emission driving algorithms, or manner of connecting to signal lines.

In one example, configurations refers to a combination of at least two of arrangement of components (e.g., light emitting elements), shape of the components, size of the components, orientation of the components, inter-component distance (e.g., inter-light emitting element distance), distribution density of the components, alignment of the components, aperture ratio of the components, or resolution (e.g., pixel per inch or PPI) of the components.

In another example, configurations refers to a combination of at least three (e.g., 4, 5, or 6) of arrangement of components (e.g., light emitting elements), shape of the components, size of the components, orientation of the components, inter-component distance (e.g., inter-light emitting element distance), distribution density of the components, alignment of the components, aperture ratio of the components, or resolution (e.g., pixel per inch or PPI) of the components.

In another example, configurations refers to a combination of all of arrangement of components (e.g., light emitting elements), shape of the components, size of the components, orientation of the components, inter-component distance (e.g., inter-light emitting element distance), distribution density of the components, alignment of the components, aperture ratio of the components, or resolution (e.g., pixel per inch or PPI) of the components.

Various appropriate light emitting elements may be used in the present display panel. Examples of appropriate light emitting elements include organic light emitting diodes, quantum dots light emitting diodes, and micro light emitting diodes. Optionally, the light emitting element is micro light emitting diode. Optionally, the light emitting element is an organic light emitting diode including an organic light emitting layer.

In some embodiments, the display panel includes pixel driving circuits. Optionally, configurations of pixel driving circuits in the first region R1 and in the second region R2 are different from each other. Optionally, configurations of pixel driving circuits in the first region R1 and in the third region R3 are different from each other. Optionally, configurations of pixel driving circuits in the second region R2 and in the third region R3 are different from each other. Optionally, configurations of pixel driving circuits in the first region R1, in the second region R2, and in the third region R3 are different from each other.

Various appropriate pixel driving circuits may be used in the present display panel. Examples of appropriate driving circuits include 3T1C, 2T1C, 4T1C, 4T2C, 5T2C, 6T1C, 7T1C, 7T2C, 8T1C, and 8T2C. In some embodiments, the respective one of the plurality of pixel driving circuits is an 7T1C driving circuit.

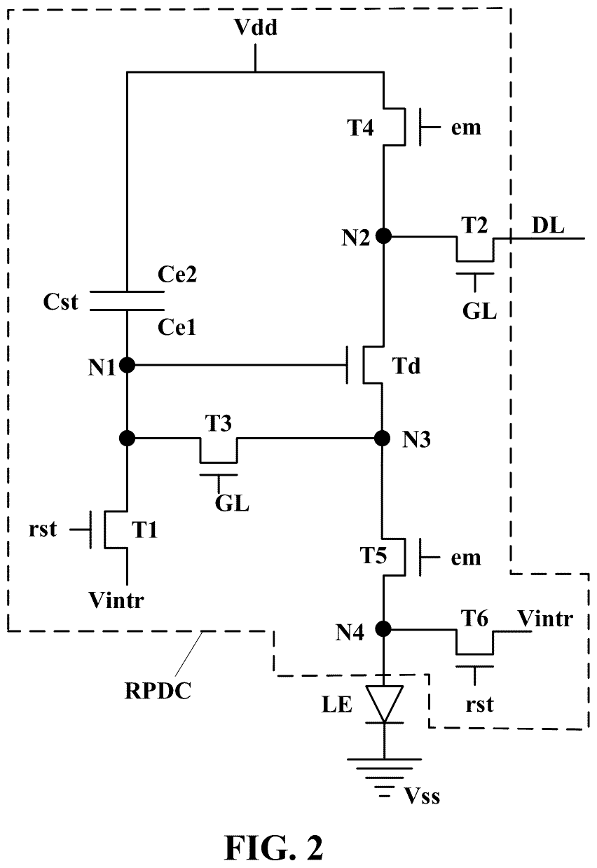

FIG. 2 is a circuit diagram illustrating the structure of a respective pixel driving circuit and a respective light emitting element in some embodiments according to the present disclosure. Referring to FIG. 2, in some embodiments, the respective pixel driving circuit RPDC includes a driving transistor Td; a storage capacitor Cst having a first capacitor electrode Ce1 and a second capacitor electrode Ce2; a first transistor T1 having a gate electrode connected to a respective reset control signal line of a plurality of reset control signal lines rst, a source electrode connected to a respective first reset signal line of a plurality of first reset signal lines Vintr, and a drain electrode connected to a first capacitor electrode Ce1 of the storage capacitor Cst and a gate electrode of the driving transistor Td; a second transistor T2 having a gate electrode connected to a respective gate line of a plurality of gate lines GL, a source electrode connected to a respective data line of a plurality of data lines DL, and a drain electrode connected to a source electrode of the driving transistor Td; a third transistor T3 having a gate electrode connected to the respective gate line, a drain electrode connected to the first capacitor electrode Ce1 of the storage capacitor Cst and the gate electrode of the driving transistor Td, and a source electrode connected to a drain electrode of the driving transistor Td; a fourth transistor T4 having a gate electrode connected to a respective light emitting control signal line of a plurality of light emitting control signal lines em, a source electrode connected to a respective first voltage supply line of a plurality of first voltage supply lines Vdd, and a drain electrode connected to the source electrode of the driving transistor Td and the drain electrode of the second transistor T2; a fifth transistor T5 having a gate electrode connected to the respective light emitting control signal line, a source electrode connected to the drain electrodes of the driving transistor Td and the source electrode of the third transistor T3, and a drain electrode connected to an anode of a light emitting element LE; and a sixth transistor T6 having a gate electrode connected to the respective reset control signal line of the plurality of reset control signal lines rst, a source electrode connected to the respective first reset signal line of the plurality of first reset signal lines Vintr, and a drain electrode connected to the drain electrode of the fifth transistor and the anode of the light emitting element LE,. The second capacitor electrode Ce2 is connected to the respective first voltage supply line and the source electrode of the fourth transistor T4.

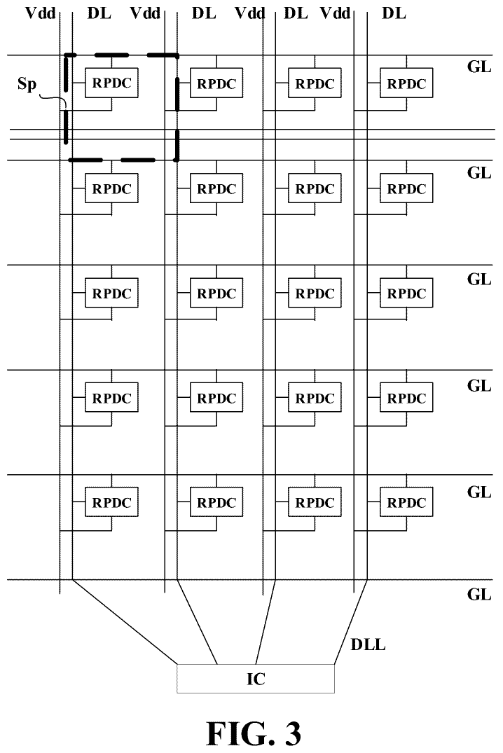

FIG. 3 is a plan view of a display panel in some embodiments according to the present disclosure. Referring to FIG. 3, the display panel includes an array of subpixels Sp. Each subpixel includes an electronic component, e.g., a light emitting element. In one example, the light emitting element is driven by a respective pixel driving circuit RPDC. The display panel includes a plurality of gate lines GL, a plurality of data lines DL, and a plurality of high voltage signal lines Vdd. Light emission in a respective subpixel is driven by a respective pixel driving circuit RPDC. In one example, a high voltage signal is input, through a respective one of the plurality of high voltage signal lines Vdd, to the respective pixel driving circuit RPDC connected to an anode of the light emitting element; a low voltage signal is input to a cathode of the light emitting element. A voltage difference between the high voltage signal (e.g., the VDD signal) and the low voltage signal (e.g., the VSS signal) is a driving voltage AV that drives light emission in the light emitting element.

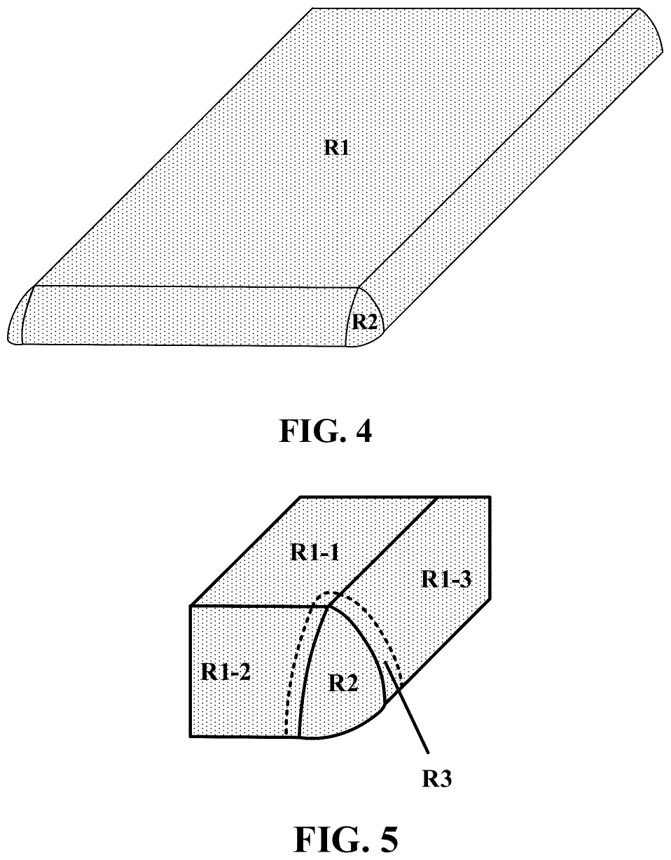

FIG. 4 is a perspective view of a display panel in some embodiments according to the present disclosure. Referring to FIG. 4, the display panel in some embodiments is a curved display panel having a three-dimensional body. The curved display panel has a first region R1 and a second region R2. In one example depicted in FIG. 4, the second region R2 of the display panel is at a corner portion of the three-dimensional body. The first region R1 of the display panel corresponds to at least a main display region of the display panel.

FIG. 5 is a zoom-in view of a corner portion of the display panel depicted in FIG. 4. Referring to FIG. 5, the second region R2 corresponds to at least a part of the corner portion of the three-dimensional body. In one example, the first region includes a first sub-region R1-1, a second sub-region R1-2, and a third sub-region R1-3. The first sub-region R1-1 corresponds to at least a portion of a top portion of the three-dimensional body, the second sub-region R1-2 corresponds to at least a portion of a first edge portion of the three-dimensional body, the third sub-region R1-3 corresponds to at least a portion of a second edge portion of the three-dimensional body. In another example, the third region R3 is between the second region R2 and the first region. For example, the third region R3 spaces apart the second region R2 from the first region R1.

Referring to FIG. 1, FIG. 4, and FIG. 5, the second region R2 in some embodiments may be a stretchable region of the display panel. In forming the three-dimensional body as depicted in FIG. 4 and FIG. 5, at least the second region R2 is subject to stretching, thereby forming the corner portion of the three-dimensional body.

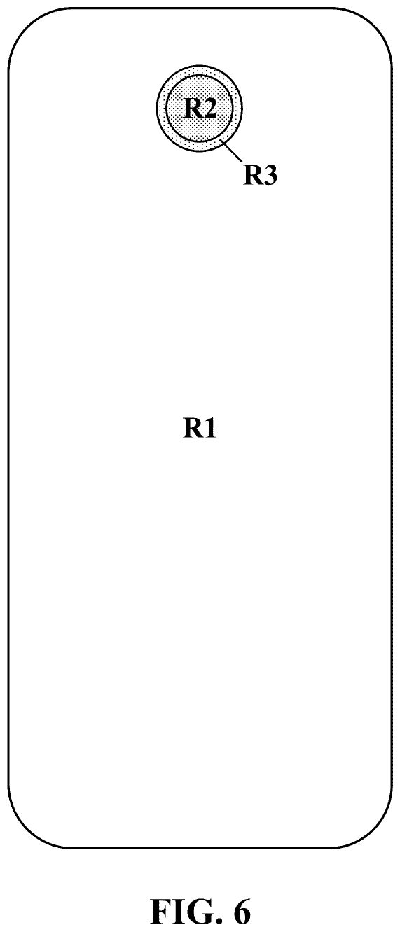

FIG. 6 is a schematic diagram of a display panel in some embodiments according to the present disclosure. Referring to FIG. 6, the display panel in some embodiments includes a window region for installing a component such as a camera or a fingerprint sensor underneath light emitting elements. The second region R2 corresponds to at least a portion of the window region. In one example, the display panel further includes a third region R3 spacing apart the second region R2 from the first region R1. In some embodiments, the display panel includes light emitting elements. Optionally, configurations of light emitting elements in the first region R1 and in the second region R2 are different from each other. Optionally, configurations of light emitting elements in the first region R1 and in the third region R3 are different from each other. Optionally, configurations of light emitting elements in the second region R2 and in the third region R3 are different from each other. Optionally, configurations of light emitting elements in the first region R1, in the second region R2, and in the third region R3 are different from each other. In some embodiments, the display panel includes pixel driving circuits. Optionally, configurations of pixel driving circuits in the first region R1 and in the second region R2 are different from each other. Optionally, configurations of pixel driving circuits in the first region R1 and in the third region R3 are different from each other. Optionally, configurations of pixel driving circuits in the second region R2 and in the third region R3 are different from each other. Optionally, configurations of pixel driving circuits in the first region R1, in the second region R2, and in the third region R3 are different from each other.

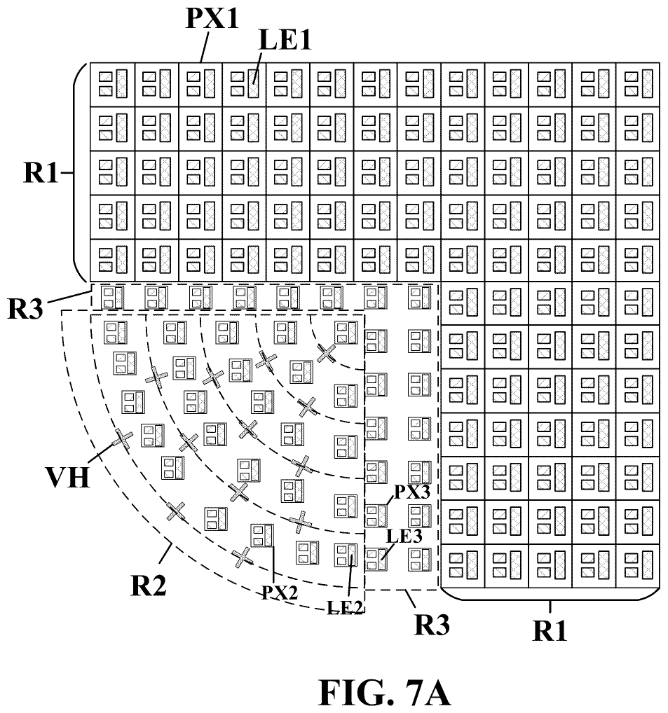

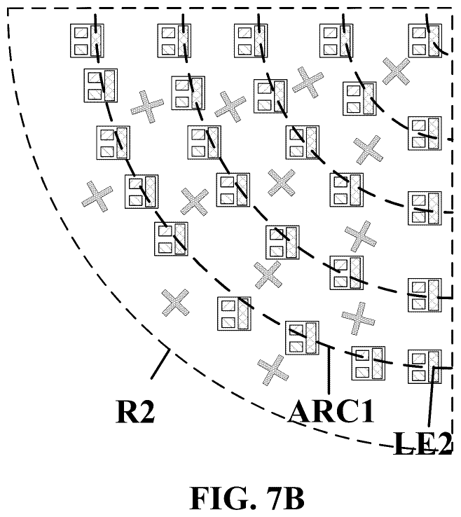

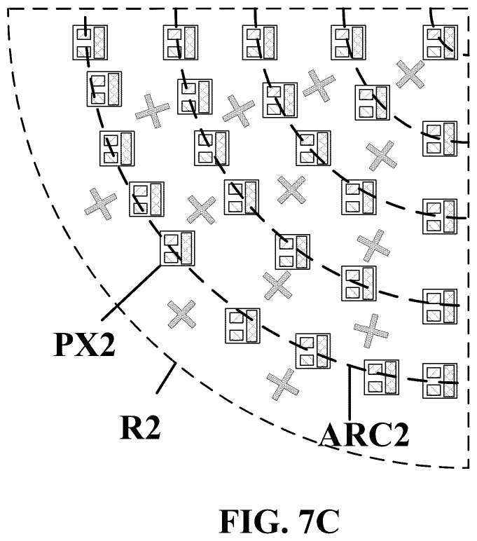

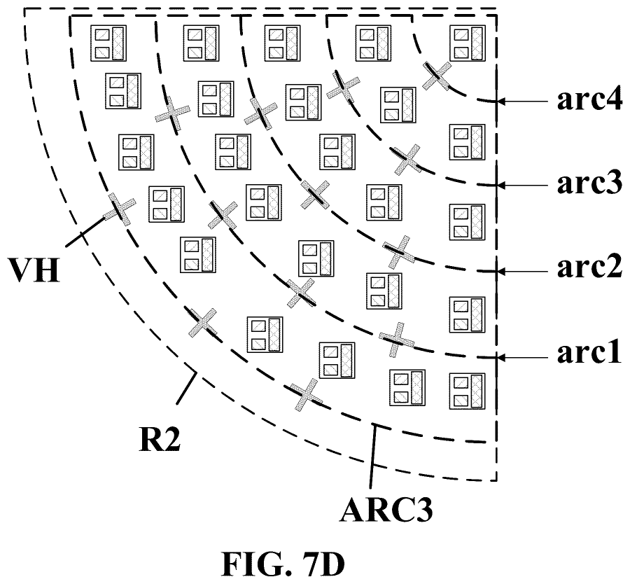

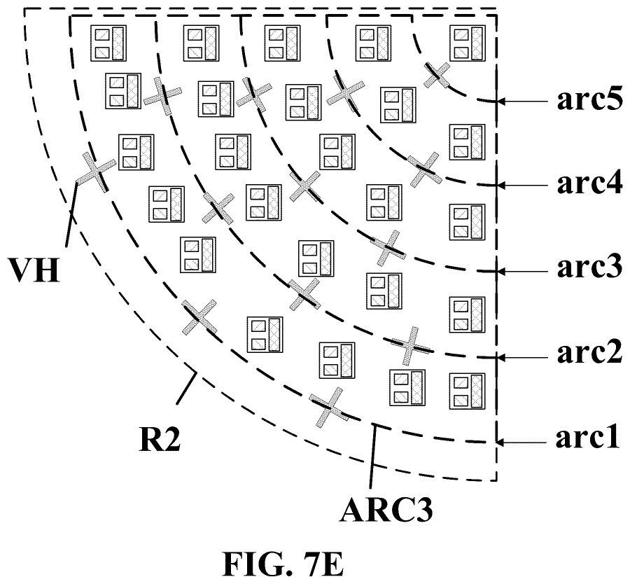

FIG. 7A illustrates configurations of components in a first region, a second region, and a third region of a display panel in some embodiments according to the present disclosure. Referring to FIG. 7A, the display panel includes a plurality of first pixels PX1 in the first region R1, a plurality of second pixels PX2 in the second region R2, and a plurality of third pixels PX3 in the third region R3. In one example depicted in FIG. 7A, a respective pixel in the display panel includes three subpixels (e.g., a red subpixel, a green subpixel, and a blue subpixel). Various implementations of the pixels may be practiced in the present display panel. For example, the respective pixel may include more than three (e.g., four) or less than three (e.g., two) subpixels.

Referring to FIG. 7A, the display panel includes a plurality of first light emitting elements LE1 in the first region R1, a plurality of second light emitting elements LE2 in the second region R2, and a plurality of third light emitting elements LE3 in the third region R3. In some embodiments, configurations of light emitting elements in at least two of the first region R1, the second region R2, and the third region R3 are different from each other. Optionally, configurations of light emitting elements in the first region R1 and in the second region R2 are different from each other. Optionally, configurations of light emitting elements in the first region R1 and in the third region R3 are different from each other. Optionally, configurations of light emitting elements in the second region R2 and in the third region R3 are different from each other. Optionally, configurations of light emitting elements in the first region R1, in the second region R2, and in the third region R3 are different from each other.

In some embodiments, sizes of the light emitting elements in at least two different regions are different from each other. In one example, a respective first light emitting element of the plurality of first light emitting elements LE1 in the first region R1 has a first size (e.g., occupied area), a respective second light emitting element of the plurality of second light emitting elements LE2 in the second region R2 has a second size, and a respective third light emitting element of the plurality of third light emitting elements LE3 in the third region R3 has a third size. In some embodiments, the respective first light emitting element, the respective second light emitting element, the respective third light emitting element are of a same color (e.g., a blue color). Optionally, with respect to light emitting elements of a same color in the first region R1, the second region R2, and the third region R3, at least two of the first size, the second size, and the third size are different from each other. In one example, the first size is greater than the second size. In another example, the first size is greater than the third size. In another example, the first size is greater than the second size and greater than the third size. In another example, the second size and the third size are substantially the same. In another example, the second size and the third size are different from each other.

In some embodiments, arrangements of the light emitting elements in at least two different regions are different from each other. In one example, light emitting elements of a same color in the first region R1 are arranged in an array comprising rows and columns. In another example, light emitting elements of a same color in the third region R3 are arranged in an array comprising rows and columns. In another example, light emitting elements of a same color (e.g., LE2) in the second region R2 are arranged along a plurality of first arcs curving toward a same direction. Optionally, the plurality of first arcs along which the light emitting elements of the same color in the second region R2 are arranged are concentric.

As used herein, the term “arc” refers to not only a partial circle, but also a partial oval, a partial ellipse, or any other appropriate curved shape.

As used herein, the term “substantially along” an arc refers to not only completely along the arc but also includes situations with deviation from the arc by no more than 1 mm, e.g., no more than 900 μm, no more than 800 μm, no more than 700 μm, no more than 600 μm, no more than 500 μm, no more than 400 μm, no more than 300 μm, no more than 200 μm, no more than 100 μm, no more than 90 μm, no more than 80 μm, no more than 70 μm, no more than 60 μm, no more than 50 μm, no more than 40 μm, no more than 30 μm, no more than 20 μm, no more than 10 μm, no more than 9 μm, no more than 8 μm, no more than 7 μm, no more than 6 μm, no more than 5 μm, no more than 4 μm, no more than 3 μm, no more than 2 μm, no more than 1 μm, no more than 0.5 μm, no more than 0.1 μm, no more than 0.05 μm, no more than 0.01 μm, or no more than 0.005 μm.

As used herein, the term “curving toward a same direction” means that a plurality of arcs (e.g., the plurality of first arcs) curving toward one or more directions that deviate from each other by no more than 45 degrees, e.g., no more than 40 degrees, no more than 35 degrees, no more than 30 degrees, no more than 25 degrees, no more than 20 degrees, no more than 15 degrees, no more than 10 degrees, no more than 5 degrees, no more than 4 degrees, no more than 3 degrees, no more than 2 degrees, no more than 1 degrees, or zero degree.

As used herein, the term “concentric” refers to that centers of a plurality of arcs (e.g., centers of the plurality of first arcs) are all inside a same circle having a radius no more than 1 mm, e.g., no more than 900 μm, no more than 800 μm, no more than 700 μm, no more than 600 μm, no more than 500 μm, no more than 400 μm, no more than 300 μm, no more than 200 μm, no more than 100 μm, no more than 90 μm, no more than 80 μm, no more than 70 μm, no more than 60 μm, no more than 50 μm, no more than 40 μm, no more than 30 μm, no more than 20 μm, no more than 10 μm, no more than 9 μm, no more than 8 μm, no more than 7 μm, no more than 6 μm, no more than 5 μm, no more than 4 μm, no more than 3 μm, no more than 2 μm, no more than 1 μm, no more than 0.5 μm, no more than 0.1 μm, no more than 0.05 μm, no more than 0.01 μm, or no more than 0.005 μm.

FIG. 7B illustrates the layout of a plurality of first arcs in a display panel in some embodiments according to the present disclosure. Referring to FIG. 7B, light emitting elements of a same color (e.g., LE2) in the second region R2 are arranged along a plurality of first arcs ARC1 curving toward a same direction. Optionally, the plurality of first arcs ARC1 along which the light emitting elements of the same color in the second region R2 are arranged are concentric.

In some embodiments, light emitting elements in at least two different regions have light emitting apertures of different sizes. In one example, a respective first light emitting element of the plurality of first light emitting elements LE1 in the first region R1 has a first light emitting aperture size, a respective second light emitting element of the plurality of second light emitting elements LE2 in the second region R2 has a second light emitting aperture size, and a respective third light emitting element of the plurality of third light emitting elements LE3 in the third region R3 has a third light emitting aperture size. In some embodiments, the respective first light emitting element, the respective second light emitting element, the respective third light emitting element are of a same color (e.g., a blue color). Optionally, with respect to light emitting elements of a same color in the first region R1, the second region R2, and the third region R3, at least two of the first light emitting aperture size, the second light emitting aperture size, and the third light emitting aperture size are different from each other. In one example, the first light emitting aperture size is greater than the second light emitting aperture size. In another example, the first light emitting aperture size is greater than the third light emitting aperture size. In another example, the first light emitting aperture size is greater than the second light emitting aperture size and greater than the light emitting aperture third size. In another example, the second light emitting aperture size and the third light emitting aperture size are substantially the same. In another example, the second light emitting aperture size and the third light emitting aperture size are different from each other.

In some embodiments, sizes of pixels in at least two different regions are different from each other. In one example, a respective first pixel of the plurality of first pixels PX1 in the first region R1 has a first pixel size (e.g., occupied pixel area), a respective second pixel of the plurality of second pixels PX2 in the second region R2 has a second pixel size, and a respective third pixel of the plurality of third pixels PX3 in the third region R3 has a third size. In some embodiments, at least two of the first pixel size, the second pixel size, and the third pixel size are different from each other. In one example, the first pixel size is greater than the second pixel size. In another example, the first pixel size is greater than the third pixel size. In another example, the first pixel size is greater than the second pixel size and greater than the third pixel size. In another example, the second pixel size and the third pixel size are substantially the same. In another example, the second pixel size and the third pixel size are different from each other.

In some embodiments, arrangements of the pixels in at least two different regions are different from each other. In one example, the plurality of first pixels PX1 in the first region R1 are arranged in an array comprising rows and columns. In another example, the plurality of third pixels PX3 in the third region R3 are arranged in an array comprising rows and columns. In another example, the plurality of second pixels PX2 in the second region R2 are arranged along a plurality of second arcs curving toward a same direction. Optionally, the plurality of second arcs along which the plurality of second pixels PX2 in the second region R2 are arranged are concentric.

FIG. 7C illustrates the layout of a plurality of second arcs in a display panel in some embodiments according to the present disclosure. Referring to FIG. 7C, the plurality of second pixels PX2 in the second region R2 are arranged along a plurality of second arcs ARC2 curving toward a same direction. Optionally, the plurality of second arcs ARC2 along which the plurality of second pixels PX2 in the second region R2 are arranged are concentric.

In some embodiments, at least two different regions of the first region R1, the second region R2, and the third region R2 have different image display resolutions, e.g., different pixel-per-inch (PPI) values. In some embodiments, the first region R1 has a first PPI, the second region R2 has a second PPI, and the third region R3 has a third PPI. In some embodiments, at least two of the first PPI, the second PPI, and the third PPI are different from each other. In one example, the first PPI is greater than the second PPI. In another example, the first PPI is greater than the third PPI. In another example, the first PPI is greater than the second PPI and greater than the third PPI. In another example, the second PPI and the third PPI are substantially the same. In another example, the second PPI and the third PPI are different from each other.

FIG. 7D illustrates the layout of a plurality of via holes in a display panel in some embodiments according to the present disclosure. Referring to FIG. 7A and FIG. 7D, the second region R2 in some embodiments includes a plurality of via holes VH. A respective via hole of the plurality of via holes VH at least partially extends into the display panel. In one example, the respective via hole is a full via hole that extends through an entire thickness of the display panel. In another example, the respective via hole is a partial via hole that extends partially into a thickness of the display panel.

In some embodiments, the plurality of via holes VH are arranged along a plurality of third arcs ARC3 curved toward a same direction. Optionally, the plurality of third arcs ARC3 are concentric.

In some embodiments, along at least multiple consecutive third arcs of the plurality of third arcs ARC3, a number of via holes along individual arcs of the multiple consecutive third arcs gradually decreases arc-by-arc. For example, referring to FIG. 7D, the plurality of third arcs ARC3 includes four consecutive third arcs, arc1, arc2, arc3, and arc4. A number of via holes along individual arcs of the multiple consecutive third arcs gradually decreases arc-by-arc, for example, gradually decreasing from 4 to 1. By having gradually decreasing the number of via holes along individual arcs arc-by-arc, the stretching tension can be more evenly distributed over the second region R2 when it is stretch to form the corner portion of the three-dimensional body of the display panel.

FIG. 7E illustrates the layout of a plurality of via holes in a display panel in some embodiments according to the present disclosure. Referring to FIG. 7E, along at least multiple consecutive third arcs of the plurality of third arcs ARC3, a size of an opening (e.g., the first line or the second line of the cross shape) of via holes along individual arcs of the multiple consecutive third arcs gradually decreases arc-by-arc. For example, referring to FIG. 7E, the plurality of third arcs ARC3 includes five consecutive third arcs, arc1, arc2, arc3, arc4, and arc5. A size of the opening of via holes along individual arcs of the multiple consecutive third arcs gradually decreases arc-by-arc. By having gradually decreasing the size of the opening of via holes along individual arcs arc-by-arc, the stretching tension can be more evenly distributed over the second region R2 when it is stretch to form the corner portion of the three-dimensional body of the display panel.

Optionally, a respective first arc of the plurality of first arcs along which multiple light emitting elements in the second region R2 are arranged is between two adjacent third arcs of the plurality of third arcs along which multiple via holes are arranged.

Optionally, a respective third arc of the plurality of third arcs along which multiple via holes are arranged is between two adjacent first arcs of the plurality of first arcs along which multiple light emitting elements in the second region R2 are arranged.

Optionally, a respective second arc of the plurality of second arcs along which multiple second pixels in the second region R2 are arranged is between two adjacent third arcs of the plurality of third arcs along which multiple via holes are arranged.

Optionally, a respective third arc of the plurality of third arcs along which multiple via holes are arranged is between two adjacent second arcs of the plurality of second arcs along which multiple second pixels in the second region R2 are arranged.

The plurality of via holes VH may have various appropriate shapes. In one example depicted in FIG. 7A, an individual via hole of the plurality of via holes VH has a cross shape. Examples of other appropriate shapes of the individual via hole include a star shape, a L shape, a diamond shape, a chevron shape, a triangular shape, a rectangular shape, a square shape, a circular shape, an elliptical shape, or a polygonal shape.

In one example, an individual via hole of the plurality of via holes VH has a cross shape comprising two intersecting lines (a first line and a second line). In another example, the plurality of third arcs are concentric, and first lines of cross shapes of the plurality of via holes VH are oriented toward a same center. As used herein, the term “oriented toward a same center” refers to that extensions of the first lines of cross shapes of the plurality of via holes VH intersect with a same circle having a radius no more than 1 mm, e.g., no more than 900 μm, no more than 800 μm, no more than 700 μm, no more than 600 μm, no more than 500 μm, no more than 400 μm, no more than 300 μm, no more than 200 μm, no more than 100 μm, no more than 90 μm, no more than 80 μm, no more than 70 μm, no more than 60 μm, no more than 50 μm, no more than 40 μm, no more than 30 μm, no more than 20 μm, no more than 10 μm, no more than 9 μm, no more than 8 μm, no more than 7 μm, no more than 6 μm, no more than 5 μm, no more than 4 μm, no more than 3 μm, no more than 2 μm, no more than 1 μm, no more than 0.5 μm, no more than 0.1 μm, no more than 0.05 μm, no more than 0.01 μm, or no more than 0.005 μm.

In some embodiments, the first region R1 and the third region R3 are free of via holes of the plurality of via holes VH, e.g., the plurality of via holes VH are limited in the second region R2.

In some embodiments, a light emission driving algorithm for driving light emission in the second region R2 is different from a light emission driving algorithm for driving light emission in the first region R1, or different from a light emission driving algorithm for driving light emission in the third region R3. Optionally, the light emission driving algorithm for driving light emission in the third region R3 is different from the light emission driving algorithm for driving light emission in the first region R1, or different from the light emission driving algorithm for driving light emission in the second region R2.

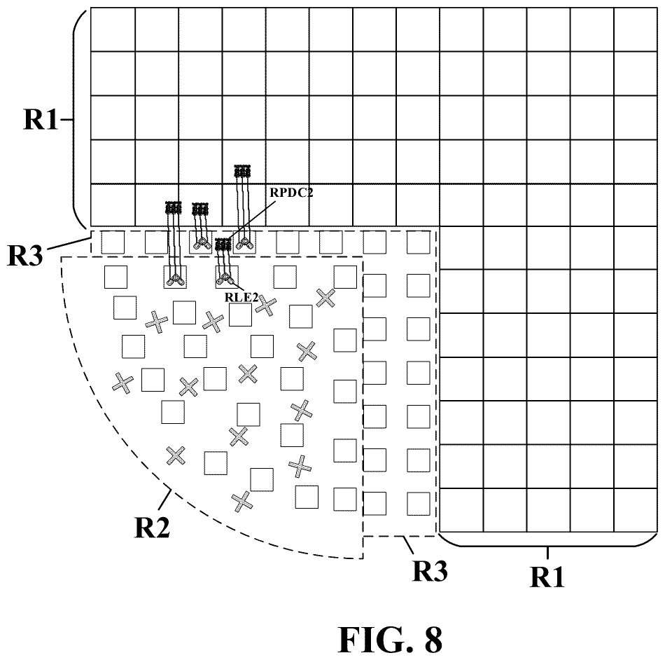

FIG. 8 illustrates configurations of components in a first region, a second region, and a third region of a display panel in some embodiments according to the present disclosure. Referring to FIG. 8, in some embodiments, a respective second pixel driving circuit RPDC2 is configured to drive light emission in a respective second light emitting element RLE2. The respective second pixel driving circuit RPDC2 is coupled to the respective second light emitting element RLE2. Optionally, the respective second light emitting element RLE2 is in the second region R2, and the respective second pixel driving circuit RPDC2 is outside the second region R2. In one example, the respective second pixel driving circuit RPDC2 is in the third region R3. In another example, the respective second pixel driving circuit RPDC2 is in the first region R1.

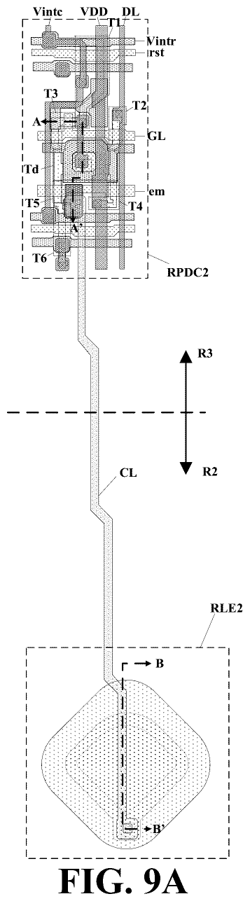

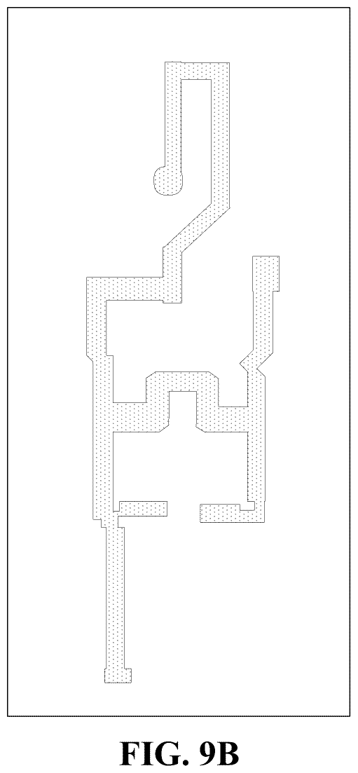

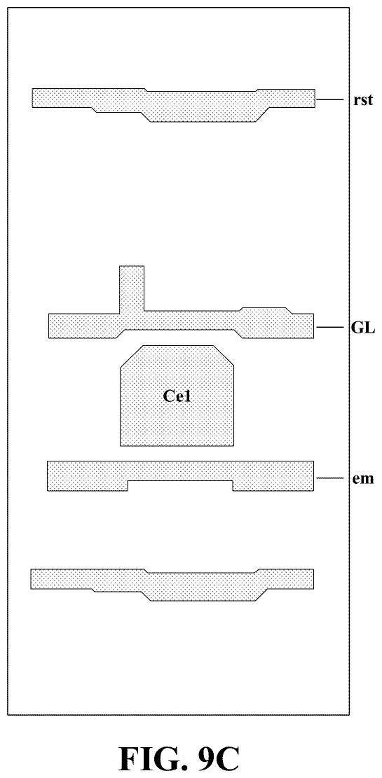

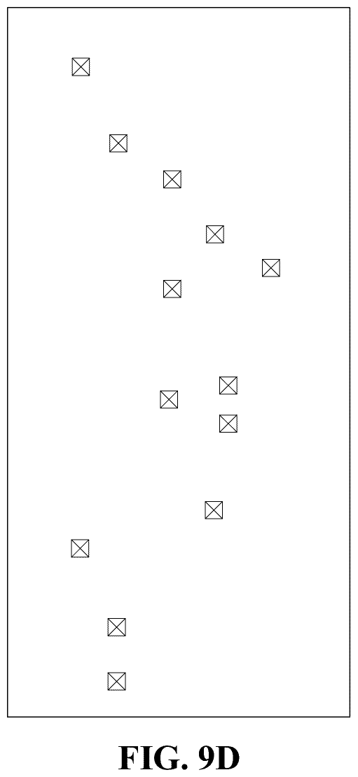

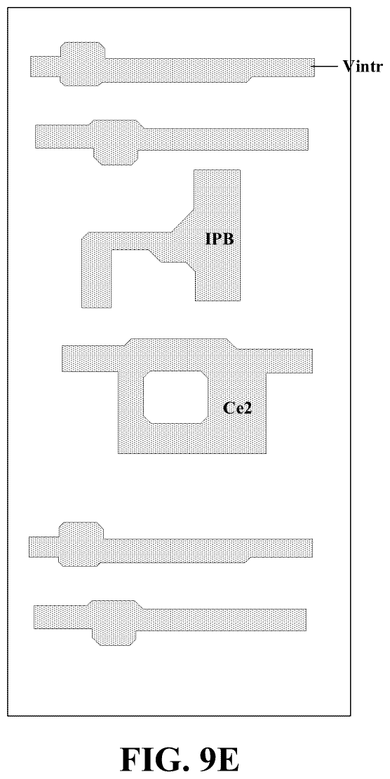

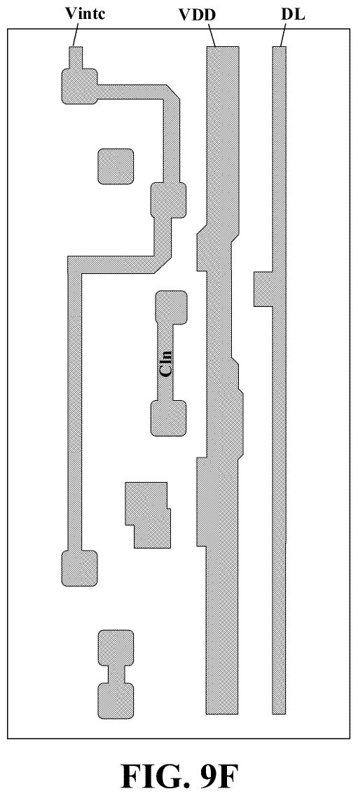

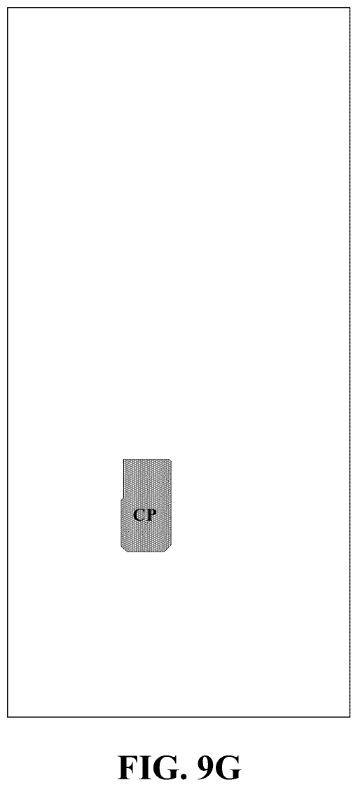

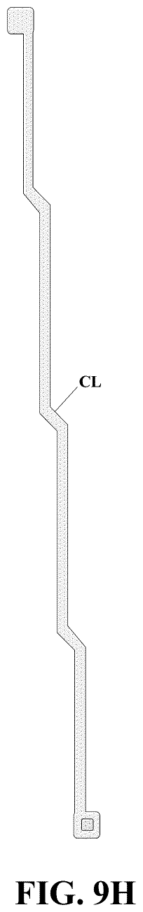

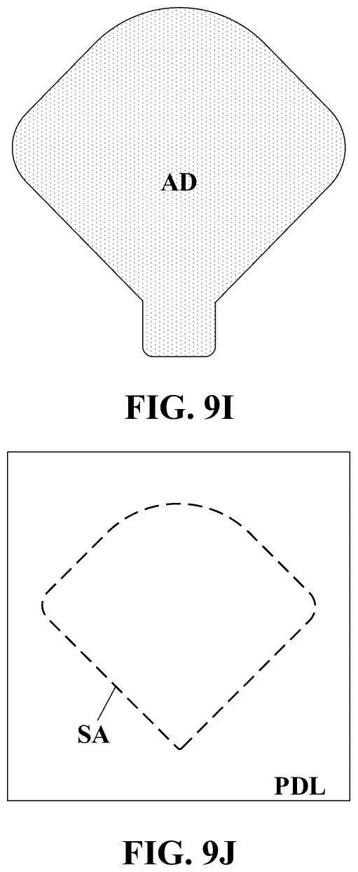

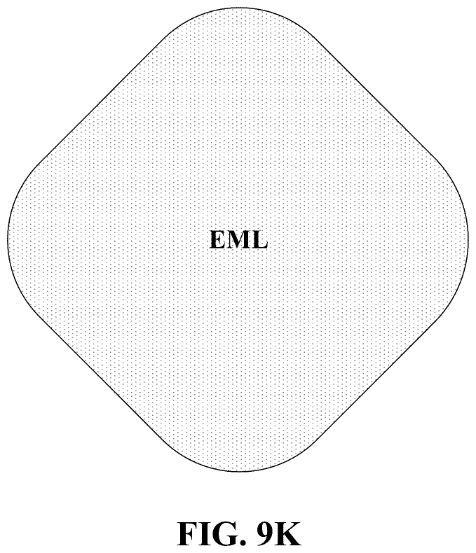

FIG. 9A illustrates the structure of a respective second pixel driving circuit and a respective second light emitting element in some embodiments according to the present disclosure. In the example depicted in FIG. 9A, the respective second light emitting element RLE2 is in the second region R2, and the respective second pixel driving circuit RPDC2 is in the third region R3.

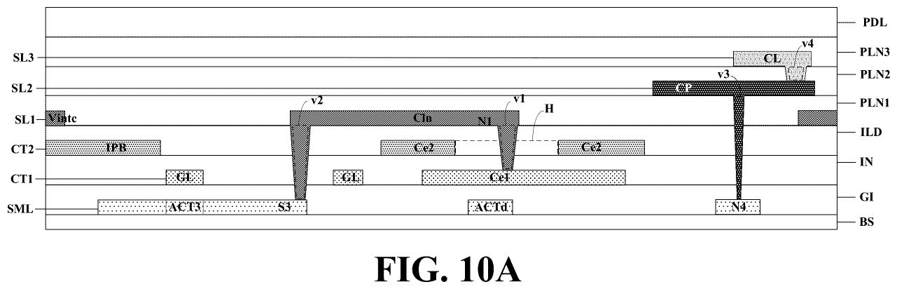

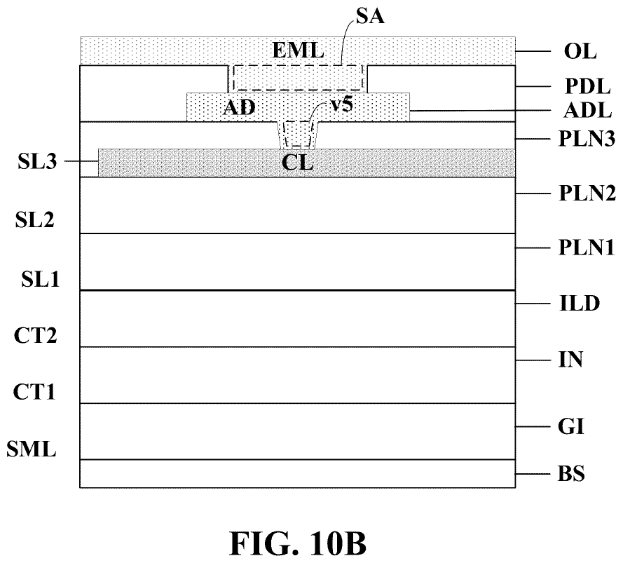

FIG. 9B illustrates the structure of a semiconductor material layer in a display panel depicted in FIG. 9A. FIG. 9C illustrates the structure of a first conductive layer in a display panel depicted in FIG. 9A. FIG. 9D illustrates the structure of an insulating layer in a display panel depicted in FIG. 9A. FIG. 9E illustrates the structure of a second conductive layer in a display panel depicted in FIG. 9A. FIG. 9F illustrates the structure of a first signal layer in a display panel depicted in FIG. 9A. FIG. 9G illustrates the structure of a second signal layer in a display panel depicted in FIG. 9A. FIG. 9H illustrates the structure of a third signal layer in a display panel depicted in FIG. 9A. FIG. 91 illustrates the structure of an anode layer in a display panel depicted in FIG. 9A. FIG. 9J illustrates the structure of a pixel definition layer in a display panel depicted in FIG. 9A. FIG. 9K illustrates the structure of a light emitting layer in a display panel depicted in FIG. 9A. FIG. 10A is a cross-sectional view along an A-A′ line in FIG. 9A. FIG. 10B is a cross-sectional view along a B-B′ line in FIG. 9A.

Referring to FIG. 9A to FIG. 9K, FIG. 10A, and FIG. 10B, in some embodiments, the display panel includes a base substrate BS, a semiconductor material layer SML on the base substrate BS, a gate insulating layer GI on a side of the semiconductor material layer SML away from the base substrate BS, a first conductive layer CT1 on a side of the gate insulating layer GI away from the semiconductor material layer SML, an insulating layer IN on a side of the first conductive layer away from the gate insulating layer GI, a second conductive layer CT2 on a side of the insulating layer IN away from the first conductive layer CT1, an inter-layer dielectric layer ILD on a side of the second conductive layer CT2 away from the insulating layer IN, a first signal line layer SL1 on a side of the inter-layer dielectric layer ILD away from the second conductive layer CT2, a first planarization layer PLN1 on a side of the first signal line layer SL1 away from the inter-layer dielectric layer ILD, a second signal line layer SL2 on a side of the first planarization layer PLN1 away from the first signal line layer SL1, a second planarization layer PLN2 on a side of the second signal line layer SL2 away from the first planarization layer PLN1, a third signal line layer SL3 on a side of the second planarization layer PLN2 away from the second signal line layer SL2, a third planarization layer PLN3 on a side of the third signal line layer SL3 away from the second planarization layer PLN2, an anode layer ADL on a side of the third planarization layer PLN3 away from the third signal line layer SL3, a pixel definition layer PDL on a side of the anode layer ADL away from the third planarization layer PLN3, and a light emitting layer EML on a side of the pixel definition layer PDL away from the anode layer ADL.

Referring to FIG. 9A to FIG. 9K, the semiconductor material layer SML in some embodiments includes active layers of the transistors, including active layers of the first transistor T1, the second transistor T2, the third transistor T3, the fourth transistor T4, the fifth transistor T5, the sixth transistor T6, and the driving transistor Td. Various appropriate semiconductor materials may be used for making the semiconductor material layer SML. Examples of appropriate semiconductor materials for making the semiconductor material layer SML include polycrystalline silicon, amorphous silicon, and metal oxides.

The first conductive layer CT1 in some embodiments includes a plurality of gate lines GL, a plurality of reset control signal lines rst, a plurality of light emitting control signal lines em, and a first capacitor electrode Ce1 of the storage capacitor Cst.

Vias extending through an insulating layer IN are depicted in FIG. 9D.

The second conductive layer CT2 in some embodiments includes an interference preventing block IPB, a second capacitor electrode Ce2 of the storage capacitor Cst, and a plurality of first reset signal lines Vintr. The interference preventing block IPB can effectively reduce crosstalk, particularly vertical crosstalk between the N1 node of the adjacent data lines.

The first signal line layer SL1 in some embodiments includes a plurality of first voltage supply lines Vdd, a node connecting line Cln, a plurality of second reset signal lines Vintc, and a plurality of data lines DL. The node connecting line Cln connects the first capacitor electrode Ce1 and the source electrode of the third transistor T3 in a respective pixel driving circuit together. The array substrate further includes a first via v1 in the hole region H and extending through the inter-layer dielectric layer ILD and the insulating layer IN. Optionally, the node connecting line Cln is connected to the first capacitor electrode Ce1 through the first via v1. In some embodiments, the first capacitor electrode Ce1 is on a side of the gate insulating layer IN away from the base substrate BS. Optionally, the array substrate further includes a second via v2. The first via v1 is in the hole region H and extends through the inter-layer dielectric layer ILD and the insulating layer IN. The second via v2 extends through the inter-layer dielectric layer ILD, the insulating layer IN, and the gate insulating layer GI. Optionally, the node connecting line Cln is connected to the first capacitor electrode Ce1 through the first via v1, and is connected to the semiconductor material layer SML through the second via v2. Optionally, the node connecting line Cln is connected to the source electrode S3 of third transistor, as depicted in FIG. 10A.

The second signal line layer SL2 in some embodiments includes a connecting pad CP, through which the N4 node is electrically connected to an anode of the respective light emitting element. Optionally, the array substrate further includes a third via v3 extending through the first planarization layer PLN1, the inter-layer dielectric layer ILD, the insulating layer IN, and the gate insulating layer GI. The connecting pad CP is connected to the N4 node through the third via v3.

The third signal line layer SL3 in some embodiments includes a plurality of connecting lines CL. A respective connecting line of the plurality of connecting lines CL electrically connects the connecting pad CP to an anode of the respective light emitting element. Optionally, the array substrate further includes a fourth via v4 extending through the second planarization layer PLN2. A respective connecting line of the plurality of connecting lines CL is connected to the connecting pad CP through the fourth via v4. Various appropriate conductive materials may be used for making the plurality of connecting lines CL. Examples of appropriate conductive materials for making the plurality of connecting lines CL include conductive metal oxides such as indium tin oxide.

The anode layer includes a plurality of anodes AD of a plurality of light emitting elements, respectively. A respective anode of the plurality of anodes AD is connected to a respective connecting line. Optionally, the array substrate further includes a fifth via v5 extending through the third planarization layer PLN3. The respective anode is connected to the respective connecting line through the fifth via v5.

The pixel definition layer PDL defines a plurality of subpixel apertures SA.

The organic layer OL in some embodiments includes a plurality of light emitting layer EML of a plurality of light emitting elements, respectively. A respective light emitting layer of the plurality of light emitting layer EML is electrically connected to a respective anode of the plurality of anodes AD.

In one example, the plurality of connecting lines CL are in a third signal line layer SL3; the second planarization layer PLN2 is on a side of the third signal line layer SL3 closer to a base substrate BS; the third planarization layer PLN3 is on a side of the third signal line layer SL3 away from the base substrate BS; the anode layer ADL is on a side of the third planarization layer PLN3 away from the third signal line layer SL3; and transistors and capacitors of the plurality of pixel driving circuits PDC are on a side of the second planarization layer PLN2 away from the third signal line layer SL3.

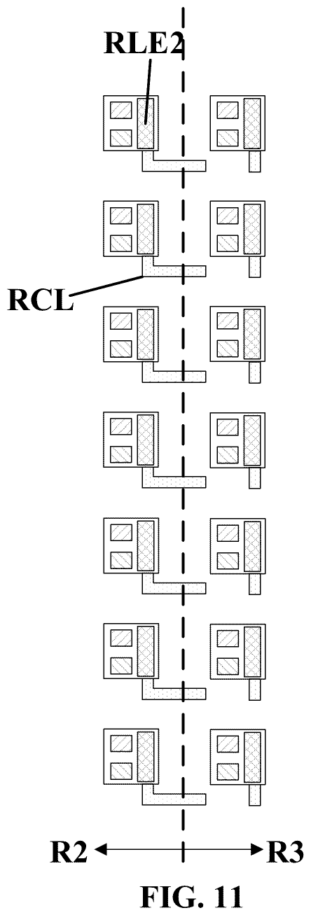

FIG. 11 illustrates connection between a respective second pixel driving circuit and a respective second light emitting element in some embodiments according to the present disclosure. Referring to FIG. 11, in some embodiments, the respective second light emitting element RLE2 is in the second region, whereas the respective second pixel driving circuit is outside the second region R2, e.g., is in the third region R3. A respective connecting line RCL of the plurality of connecting lines connects the respective second light emitting element RLE2 in the second region R2 to the respective second pixel driving circuit in the third region R3.

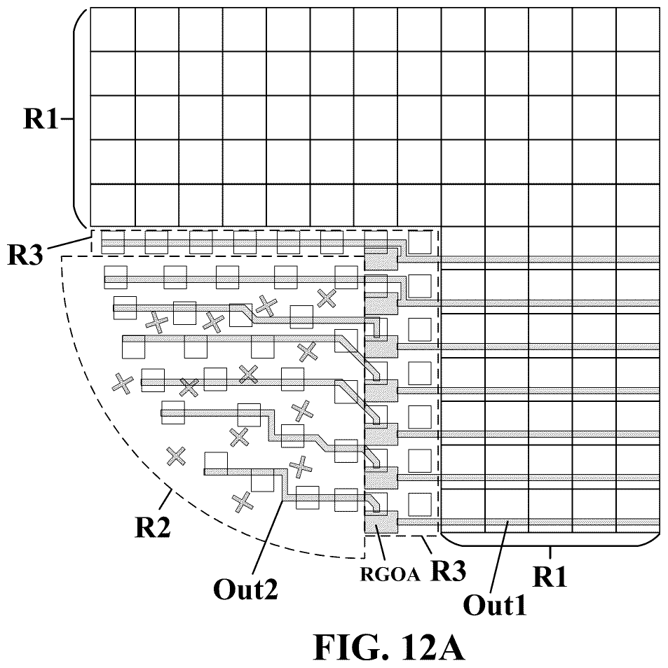

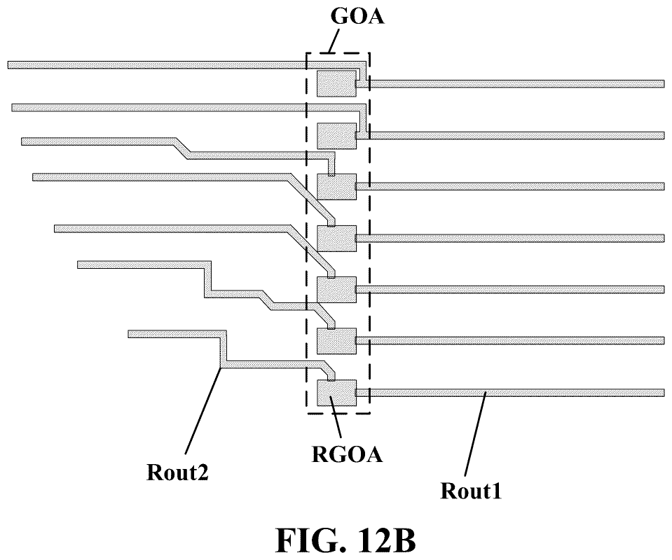

FIG. 12A illustrates configurations of components in a first region, a second region, and a third region of a display panel in some embodiments according to the present disclosure. FIG. 12B is a schematic diagram illustrating the structure of a scan circuit in a display panel in some embodiments according to the present disclosure. Referring to FIG. 12A and FIG. 12B, the display panel in some embodiments further includes a scan circuit GOA comprising a plurality of stages, and configured to provide control signals to different rows of subpixels. In one example, the scan circuit is a gate scanning signal generating circuit configured to provide gate scanning signals to the plurality of rows of subpixels. In another example, the scan circuit is a reset control signal generating circuit configured to provide reset control signal to the plurality of rows of subpixels. In another example, the scan circuit is a light emitting control signal generating circuit configured to provide light emitting control signal to the plurality of rows of subpixels.

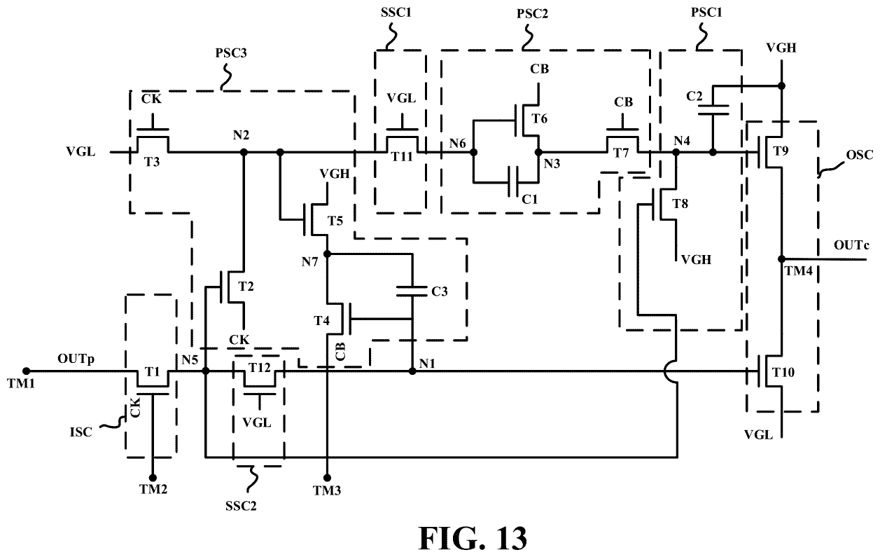

FIG. 13 is a circuit diagram of a respective scan unit of a scan circuit in some embodiments according to the present disclosure. Referring to FIG. 13, the respective scan unit in some embodiments includes an input subcircuit ISC, an output subcircuit OSC, a first processing subcircuit PSC1, a second processing subcircuit PSC2, a third processing subcircuit PSC3, a first stabilizing subcircuit SSC1, and a second stabilizing subcircuit SSC2.

In some embodiments, the output subcircuit OSC is configured to supply the voltage of a first power supply VGH or a second power supply VGL to an output terminal TM4 in response to voltages of a fourth node N4 and a first node N1. Optionally, the output subcircuit OSC includes a ninth transistor T9 and a tenth transistor T10.

The ninth transistor T9 is coupled between a first power supply VGH and the output terminal TM4. A gate electrode of the ninth transistor T9 is coupled to the fourth node N4. The ninth transistor T9 may be turned on or off depending on the voltage of the fourth node N4. Optionally, when the ninth transistor T9 is turned on, the voltage of the first power supply VGH is provided to the output terminal TM4, which (annotated as OUTc in FIG. 13) may be transmitted to a n-th gate line and used as a gate driving signal having a gate-on level.

The tenth transistor T10 is coupled between the output terminal TM4 and a second power supply VGL. A gate electrode of the tenth transistor T10 is coupled to the first node N1. The tenth transistor T10 may be turned on or off depending on the voltage of the first node N1. Optionally, when the tenth transistor T10 is turned on, the voltage of the second power supply VGL is provided to the output terminal TM4, which (annotated as OUTc in FIG. 13) may be provided to a n-th gate line and used as a gate driving signal having a gate-off level. In one example, when the gate driving signal has a gate-off level, it may be understood that the gate driving signal is not provided.

In some embodiments, the input subcircuit ISC is configured to control the voltages of the first node N1 and a fifth node N5 in response to signals provided to the first input terminal TM1 and the second input terminal TM2, respectively. Optionally, the input subcircuit ISC includes a first transistor T1.

The first transistor T1 is coupled between the first input terminal TM1 and the fifth node N5. A gate electrode of the first transistor T1 is coupled to the second input terminal TM2. When the first clock signal CK is provided to the second input terminal TM2, the first transistor T1 is turned on to electrically couple the first input terminal TM1 with the fifth node N5.

In some embodiments, the first processing subcircuit PSC1 is configured to control the voltage of the fourth node N4 in response to the voltages of the first node N1 and the fifth node N5. Optionally, the first processing subcircuit PSC1 includes an eighth transistor T8 and a second capacitor C2.

The eighth transistor T8 is coupled between the first power supply VGH and the fourth node N4. A gate electrode of the eighth transistor T8 is coupled to the fifth node N5. The eighth transistor T8 may be turned on or off depending on the voltage of the fifth node N5. Optionally, when the eighth transistor T8 is turned on, the voltage of the first power supply VGH may be provided to the fourth node N4.

The second capacitor C2 is coupled between the first power supply VGH and the fourth node N4. Optionally, the second capacitor C2 is configured to charge a voltage to be applied to the fourth node N4. Optionally, the second capacitor C2 is configured to stably maintain the voltage of the fourth node N4.

In some embodiments, the second processing subcircuit PSC2 is coupled to a sixth node N6, and is configured to control the voltage of the fourth node N4 in response to a signal input to the third input terminal TM3. Optionally, the second processing subcircuit PSC2 includes a sixth transistor T6, a seventh transistor T7, and a first capacitor C1.

A first terminal of the first capacitor C1 is coupled to the sixth node N6, and a second terminal of the first capacitor C1 is coupled to a third node N3 that is a common node between the sixth transistor T6 and the seventh transistor T7.

The sixth transistor T6 is coupled between the third node N3 and the sixth node N6. A gate electrode of the sixth transistor T6 is coupled to the sixth node N6. The sixth transistor T6 may be turned on depending on the voltage of the sixth node N6 so that a voltage corresponding to the second clock signal CB provided to the third input terminal TM3 may be applied to the third node N3.

The seventh transistor T7 is coupled between the fourth node N4 and the third node N3. A gate electrode of the seventh transistor T7 is coupled to the third input terminal TM3. The seventh transistor T7 may be turned on in response to the second clock signal CB provided to the third input terminal TM3, and thus, applies the voltage of the first power supply VGH to the third node N3.

In some embodiments, the third processing subcircuit PSC3 is configured to control the voltage of the second node N2. Optionally, the third processing subcircuit PSC3 includes a second transistor T2, a third transistor T3, a fourth transistor T4, a fifth transistor T5, and a third capacitor C3.

A first electrode of the third capacitor C3 is coupled to the first node N1, and a second electrode of the third capacitor C3 is coupled to a seventh node N7 that is a common node between the fourth transistor T4 and the fifth transistor T5.

The fifth transistor T5 is coupled between the first power supply VGH and the seventh node N7. A gate electrode of the fifth transistor T5 is coupled to the second node N2. The fifth transistor T5 may be turned on or off depending on the voltage of the second node N2.

The fourth transistor T4 is coupled between the seventh node N7 and the third input terminal TM3. A gate electrode of the fourth transistor T4 is coupled to the first node N1. The fourth transistor T4 may be turned on or off depending on the voltage of the first node N1.

The second transistor T2 is coupled between the second node N2 and the second input terminal TM2. A gate electrode of the second transistor T2 is coupled to the fifth node N5.

The third transistor T3 is coupled between the second node N2 and the second power supply VGL. A gate electrode of the third transistor T3 is coupled to the second input terminal TM2. When the first clock signal CK is provided to the second input terminal TM2, the third transistor T3 may be turned on so that the voltage of the second power supply VGL may be provided to the second node N2.

In some embodiments, the first stabilizing subcircuit SSC1 is coupled between the second processing subcircuit PSC2 and the third processing subcircuit PSC3. Optionally, the first stabilizing subcircuit SSC1 is configured to limit a voltage drop width of the second node N2. Optionally, the first stabilizing subcircuit SSC1 includes an eleventh transistor T11.

The eleventh transistor T11 is coupled between the second node N2 and the sixth node N6. A gate electrode of the eleventh transistor T11 is coupled to the second power supply VGL. Since the second power supply VGL has a gate-on level voltage, the eleventh transistor T11 may always remain turned on. Therefore, the second node N2 and the sixth node N6 may be maintained at the same voltage, and operated as substantially the same node.

In some embodiments, the second stabilizing subcircuit SSC2 is coupled between the first node N1 and the fifth node N5. Optionally, the second stabilizing subcircuit SSC2 is configured to limit a voltage drop width of the first node N1. Optionally, the second stabilizing subcircuit SSC2 includes a twelfth transistor T12.

The twelfth transistor T12 is coupled between the first node N1 and the fifth node N5. A gate electrode of the twelfth transistor T12 is coupled to the second power supply VGL. Since the second power supply VGL has a gate-on level voltage, the twelfth transistor T12 may always remain turned on. Therefore, the first node N1 and the fifth node N5 may be maintained at the same voltage, and operated as substantially the same node.

In some embodiments, each of the first to twelfth transistors T1 to T12 may be formed of a p-type transistor. In some embodiments, the gate-on voltage of the first to twelfth transistors T1 to T12 may be set to a low level, and the gate-off voltage thereof may be set to a high level.

Referring to FIG. 12A and FIG. 12B again, in some embodiments, a respective scan unit RGOA of the scan circuit GOA is at least partially (e.g., completely) disposed in the third region R3, and is configured to provide scan signals to subpixels in the second region R2 and subpixels in the first region R1. In some embodiments, the display panel includes a respective first output line Rout1 and a respective second output line Rout2 connected to the respective scan unit RGOA. The respective first output line Rout1 is configured to transmit control signals from the respective scan unit RGOA to a row of subpixels in the first region R1, and the respective second output line Rout2 is configured to transmit control signals from the respective scan unit RGOA to a row of subpixels in the third region R3.

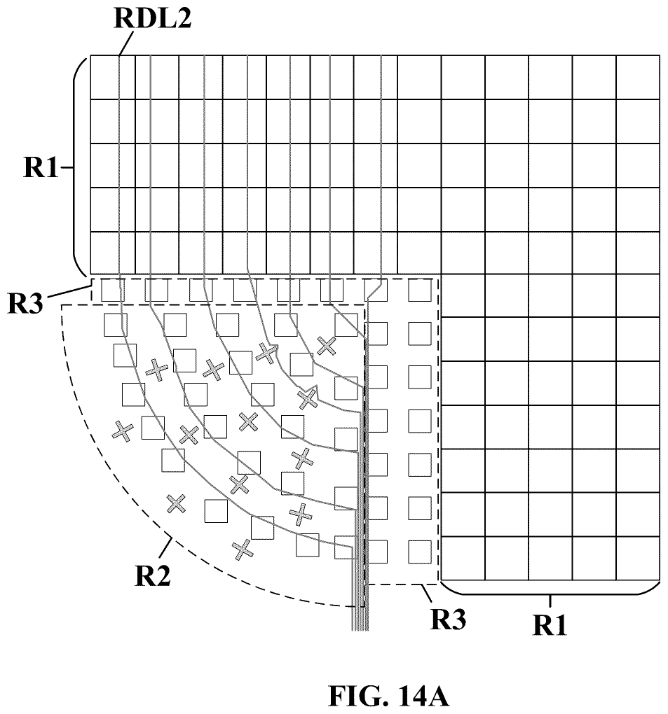

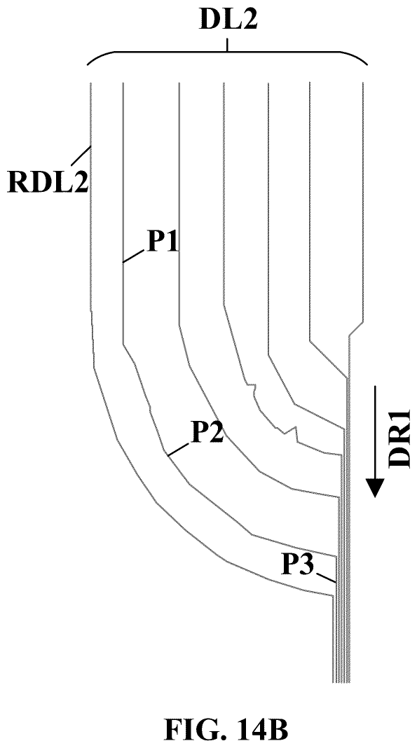

FIG. 14A illustrates configurations of components in a first region, a second region, and a third region of a display panel in some embodiments according to the present disclosure. FIG. 14B is a schematic diagram illustrating the layout of a plurality of data lines in a display panel in some embodiments according to the present disclosure. Referring to FIG. 3, FIG. 14A, and FIG. 14B, the display panel in some embodiments includes a plurality of data lines DL. The plurality of data lines DL includes a plurality of second data lines DL2 configured to provide data signals to subpixels in the second region R2. A respective second data line RDL2 at least partially passes through the second region R2.

In one example, portions of the plurality of second data lines DL2 in the second region R2 extend along a plurality of fourth arcs, respectively. Optionally, the plurality of fourth arcs curve toward a same direction. Optionally, the plurality of fourth arcs are concentric.

In some embodiments, a respective second data line RDL2 includes a first portion P1, a second portion P2, and a third portion P3. The second portion P2 extends along a respective fourth arc of the plurality of fourth arcs. The second portion P2 connects the first portion P1 and the third portion P3 together. The first portion P1 and the third portion P3 extend along directions substantially parallel to each other, e.g., substantially parallel to a first direction DR1. As used herein, the term “substantially parallel” means that an angle is in the range of 0 degree to approximately 45 degrees, e.g., 0 degree to approximately 5 degrees, 0 degree to approximately 10 degrees, 0 degree to approximately 15 degrees, 0 degree to approximately 20 degrees, 0 degree to approximately 25 degrees, 0 degree to approximately 30 degrees.

In some embodiments, first portions of the plurality of second data lines DL2 extend along directions substantially parallel to each other; and third portions of the plurality of second data lines DL2 extend along directions substantially parallel to each other. Optionally, first inter-line distances between immediately adjacent first portions is greater than (e.g., by at least twice, at least three times, at least four times, at least five times, at least six times, at least seventh times, at least eight times, at least nine times, or at least ten times) second inter-line distances between immediately adjacent third portions. In one example, an average of the first inter-line distances is substantially the same as an average width of a pixel in the first region R1. In another example, a sum of the second inter-line distances is less than or equal to an average width of a pixel in the second region R2 or in the third region R3. In another example, the third portions are between two adjacent columns of pixels. In another example, the third portions are between a column of pixels in the second region R2 and a column of pixels in the third region R3, the column of pixels in the second region R2 and the column of pixels in the third region R3 being immediately adjacent to each other.

In some embodiments, a respective second data line RDL2 extends first in the first region R1, then from the first region R1 into the third region R3, and then from the third region R3 into the second region R2. Optionally, the first portion P1 is at least partially in the first region R1, the second portion P2 is at least partially in the second region R2. In one example, the third portion P3 is between a column of pixels in the second region R2 and a column of pixels in the third region R3, the column of pixels in the second region R2 and the column of pixels in the third region R3 being immediately adjacent to each other.

The respective second data line RDL2 may be disposed in various appropriate layers. In one example, the respective second data line RDL2 is in the first signal line layer (e.g., SL1 in FIG. 10A).

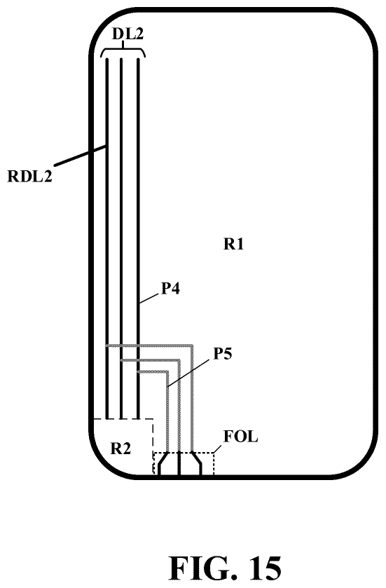

FIG. 15 is a schematic diagram illustrating the layout of a plurality of data lines in a display panel in some embodiments according to the present disclosure. Referring to FIG. 15, the respective second data line RDL2 in some embodiments may include portions in different layers. In some embodiments, the respective second data line RDL2 includes a fourth portion P4 at least partially (e.g., completely) in the first region R1 and a fifth portion P5 also at least partially (e.g., completely) in the first region R1. The fourth portion P4 is absent in the second region R2, and the fifth portion P5 is also absent in the second region R2. The fifth portion P5 is connected to a fan-out line FOL outside of the second region R2, which in turn may be connected to an integrated circuit. By having this layout, the second region R2 is free of fan-out lines. When stretching the second region R2 to form a corner region of the display panel (e.g., the corner portion depicted in FIG. 4), line breaks in the second region R2 can be obviated because the fan-out lines (as well as other signal lines) are disposed outside the second region R2.

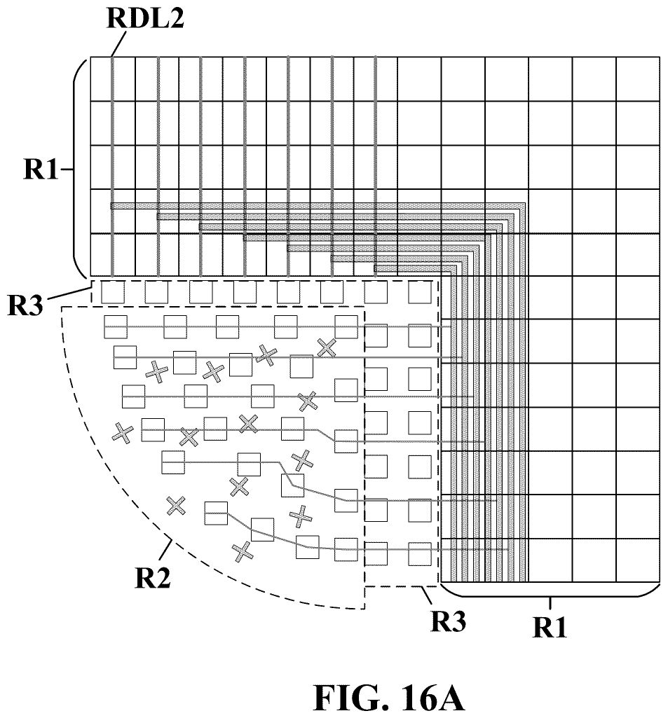

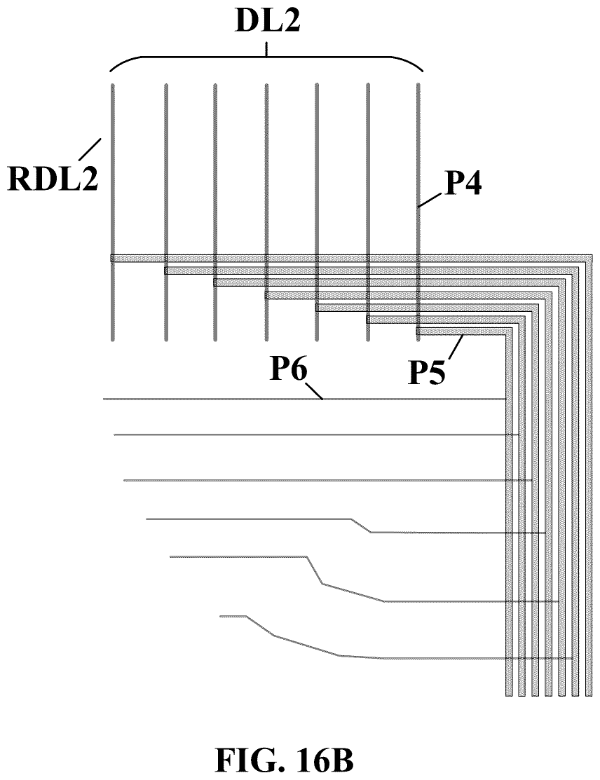

FIG. 16A illustrates configurations of components in a first region, a second region, and a third region of a display panel in some embodiments according to the present disclosure. FIG. 16B is a schematic diagram illustrating the layout of a plurality of data lines in a display panel in some embodiments according to the present disclosure. Referring to FIG. 16A and FIG. 16B, the respective second data line RDL2 in some embodiments includes a fourth portion P4, a fifth portion P5, and a sixth portion P6. The fifth portion P5 connects the fourth portion P4 and the sixth portion P6 together. Optionally, the fourth portion P4 is at least partially (e.g., completely) in the first region R1, the fifth portion P5 is also at least partially (e.g., completely) in the first region R1, and the sixth portion P6 is at least partially in the second region R2. In one example, the sixth portion P6 extends from the first region R1, through the third region R3, into the second region R2. Optionally, the fourth portion P4 is absent in the second region R2, and the fifth portion P5 is also absent in the second region R2.

Referring to FIG. 15, FIG. 16A, and FIG. 16B, the fourth portion P4 is connected to subpixels in the first region R1 and configured to provide data signals to subpixels therein; the sixth portion P6 is connected to subpixels in the second region R2 and configured to provide data signals to subpixels therein; the fifth portion P6 is connected to the fan-out line and in turn connected to an integrated circuit for receiving data signals.

In some embodiments, the fourth portion P4 is in the first signal line layer (e.g., SL1 in FIG. 10A), and the fifth portion P5 is in the third signal line layer (e.g., SL3 in FIG. 10A). In one example, the sixth portion P6 is in the first signal line layer. In another example, the sixth portion P6 is in the third signal line layer.

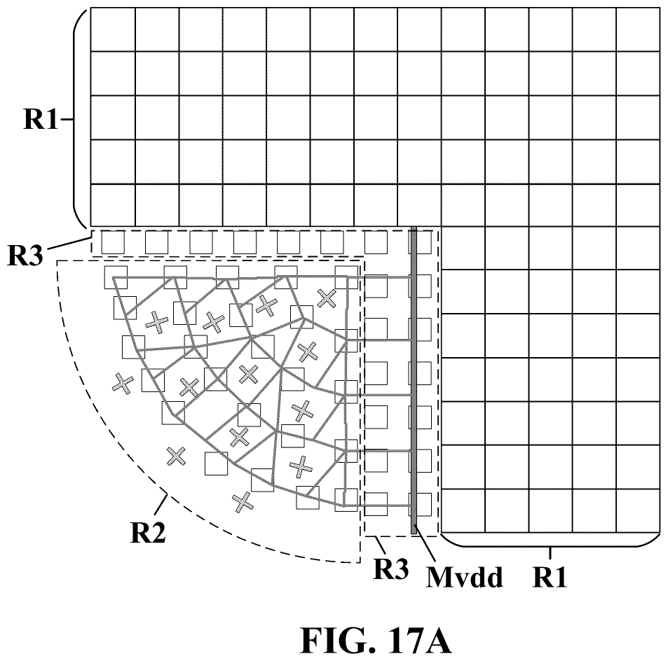

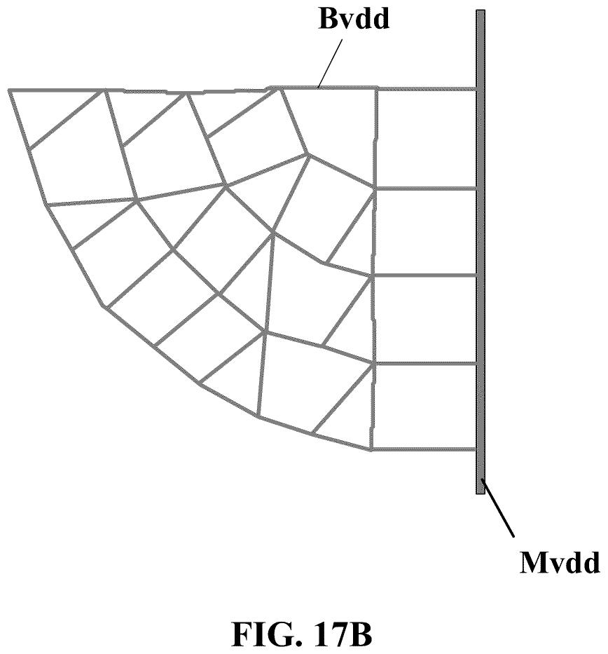

FIG. 17A illustrates configurations of components in a first region, a second region, and a third region of a display panel in some embodiments according to the present disclosure. FIG. 17B is a schematic diagram illustrating the layout of first voltage supply lines in a display panel in some embodiments according to the present disclosure. Referring to FIG. 17A and FIG. 17B, the display panel in some embodiments includes a main first voltage supply line Mvdd configured to transmit a voltage signal (e.g., a VDD signal) to the subpixels in the second region R2. The display panel optionally further includes a plurality of branch first voltage supply lines Bvdd connected to the main first voltage supply line Mvdd. Optionally, the plurality of branch first voltage supply lines Bvdd form an interconnected first voltage supply network in the second region R2.

The main first voltage supply line Mvdd and the plurality of branch first voltage supply lines Bvdd may be disposed in various appropriate layers. In one example, the main first voltage supply line Mvdd and the plurality of branch first voltage supply lines Bvdd are in the second signal line layer (e.g., SL2 in FIG. 10A).

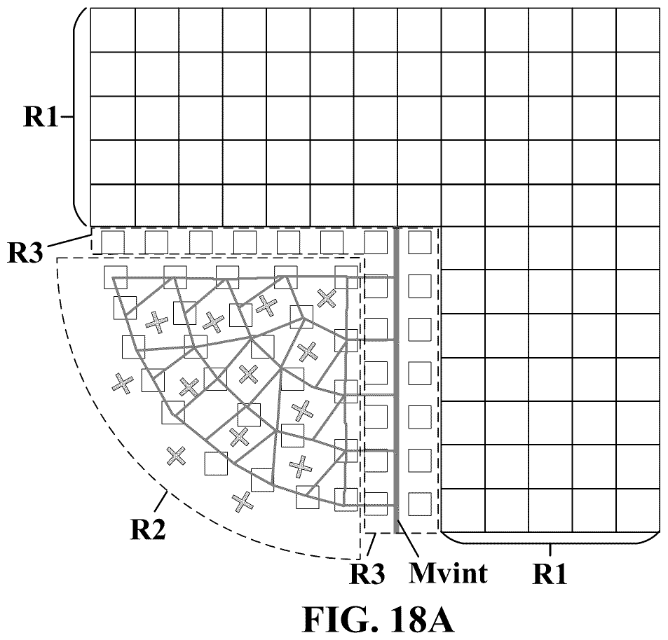

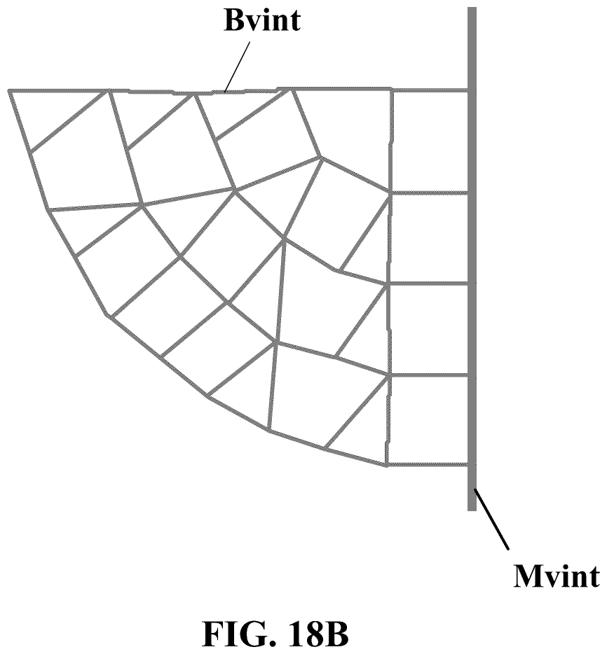

FIG. 18A illustrates configurations of components in a first region, a second region, and a third region of a display panel in some embodiments according to the present disclosure. FIG. 18B is a schematic diagram illustrating the layout of reset signal lines in a display panel in some embodiments according to the present disclosure. Referring to FIG. 18A and FIG. 18B, the display panel in some embodiments includes a main reset signal line Mvint configured to transmit a reset signal to the subpixels in the second region R2. The display panel optionally further includes a plurality of branch reset signal lines Bvint connected to the main reset signal line Mvint. Optionally, the plurality of branch reset signal lines Bvint form an interconnected reset signal network in the second region R2.

The main reset signal line Mvint and the plurality of branch reset signal lines Bvint may be disposed in various appropriate layers. In one example, the main reset signal line Mvint and the plurality of branch reset signal lines Bvint are in the second conductive layer (e.g., CT2 in FIG. 10A). In another example, the interconnected reset signal network may include portions in the first signal line layer (e.g., SL1 in FIG. 10A) to avoid intersection with other signal lines in the second conductive layer.

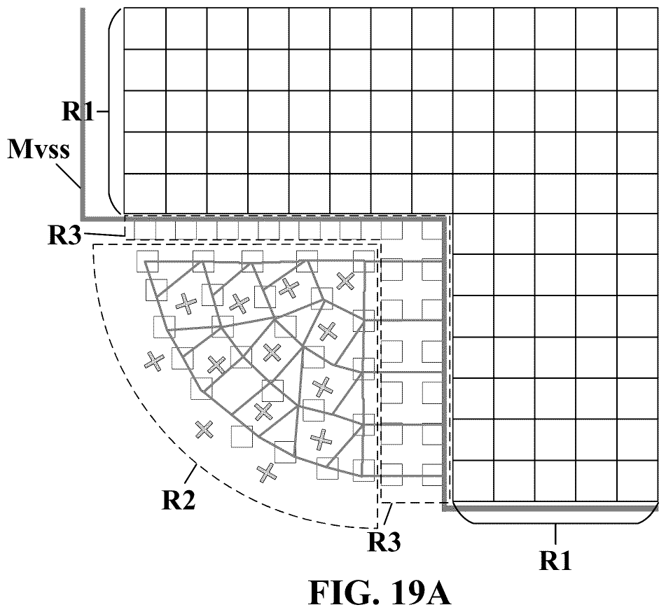

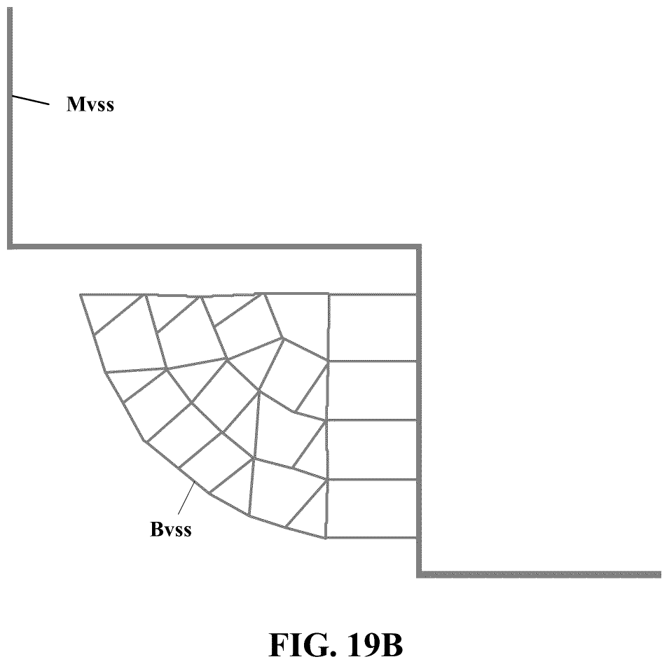

FIG. 19A illustrates configurations of components in a first region, a second region, and a third region of a display panel in some embodiments according to the present disclosure. FIG. 19B is a schematic diagram illustrating the layout of second voltage supply lines in a display panel in some embodiments according to the present disclosure. Referring to FIG. 19A and FIG. 19B, the display panel in some embodiments includes a main second voltage supply line Mvss configured to transmit a voltage signal (e.g., a VSS signal) to the subpixels in the second region R2. The display panel optionally further includes a plurality of branch second voltage supply lines Bvss connected to the main second voltage supply line Mvss. Optionally, the plurality of branch second voltage supply lines Bvss form an interconnected second voltage supply network in the second region R2.

The main second voltage supply line Mvss and the plurality of branch second voltage supply lines Bvss may be disposed in various appropriate layers. In one example, the main second voltage supply line Mvss and the plurality of branch second voltage supply lines Bvss are in the third signal line layer (e.g., SL3 in FIG. 10A).

In some embodiments, the display panel further includes a cathode layer, e.g., a unitary cathode layer as a cathode for the plurality of light emitting elements in the display panel. In some embodiments, the cathode layer is connected (e.g., through vias) to a second voltage supply line in the first region R1. Optionally, the cathode layer in the second region R2 is not directly connected (e.g., not directly connected through vias) to the main second voltage supply line Mvss in the third region R3.

In another aspect, the present invention provides a display apparatus, including the array substrate described herein or fabricated by a method described herein, and one or more integrated circuits connected to the array substrate. Examples of appropriate display apparatuses include, but are not limited to, an electronic paper, a mobile phone, a tablet computer, a television, a monitor, a notebook computer, a digital album, a GPS, etc. Optionally, the display apparatus is an organic light emitting diode display apparatus. Optionally, the display apparatus is a liquid crystal display apparatus.

In another aspect, the present invention provides a method of fabricating a display panel. In some embodiments, the method includes forming light emitting elements and pixel driving circuits in a first region, and at least one of a second region or a third region, the third region when present, at least partially spacing apart the first region and the second region. Optionally, configurations of light emitting elements in at least two of the first region, the second region, and the third region are different from each other. Optionally, configurations of pixel driving circuits in at least two of the first region, the second region, and the third region are different from each other.

The foregoing description of the embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

1. A display panel, comprising light emitting elements and pixel driving circuits in a first region and at least one of a second region or a third region, the third region, when present, at least partially spacing apart the first region and the second region;
configurations of light emitting elements in at least two of the first region, the second region, and the third region are different from each other; and
configurations of pixel driving circuits in at least two of the first region, the second region, and the third region are different from each other.

2. The display panel of claim 1, comprises a plurality of first light emitting elements in the first region, a plurality of second light emitting elements in the second region, and a plurality of third light emitting elements in the third region;
light emitting elements in at least two of the first region, the second region, and the third region have different sizes, arrangements, and light emitting apertures.

3. The display panel of claim 1, wherein the display panel comprises a plurality of first pixels in the first region, a plurality of second pixels in the second region, and a plurality of third pixels in the third region;
pixels in at least two of the first region, the second region, and the third region have different sizes, arrangements, and resolutions; and
a first pixel size of the plurality of first pixels is greater than a second pixel size of the plurality of second pixels.

4. The display panel of claim 3, wherein the plurality of first pixels in the first region are arranged in an array comprising rows and columns; and
the plurality of second pixels in the second region are arranged along a plurality of second arcs curving toward a same direction.

5. The display panel of claim 4, wherein the plurality of second arcs along which the plurality of second pixels in the second region are arranged are concentric.

6. The display panel of claim 3, wherein the plurality of first pixels has a first pixel-per-inch value;
the plurality of second pixels has a second pixel-per-inch value; and
the first pixel-per-inch value is greater than the second pixel-per-inch value.

7. The display panel of claim 1, wherein light emitting elements of a same color in the second region are arranged along a plurality of first arcs curving toward a same direction; and
the display panel includes a plurality of second pixels in the second region arranged along a plurality of second arcs curving toward a same direction.

8. The display panel of claim 7, wherein the plurality of first arcs are concentric, and the plurality of second arcs are concentric.

9. The display panel of claim 1, wherein the second region comprises a plurality of via holes at least partially extending into the display panel.

10. The display panel of claim 9, wherein the plurality of via holes are arranged along a plurality of third arcs curved toward a same direction.

11. The display panel of claim 10, wherein the plurality of third arcs are concentric.

12. The display panel of claim 11, wherein an individual via hole of the plurality of via holes has a cross shape comprising a first line and a second line intersecting each other; and
first lines of cross shapes of the plurality of via holes are oriented toward a same center.

13. The display panel of claim 10, wherein light emitting elements of a same color in the second region are arranged along a plurality of first arcs curving toward a same direction;
a respective first arc of the plurality of first arcs is between two adjacent third arcs of the plurality of third arcs; and
a respective third arc of the plurality of third arcs is between two adjacent first arcs of the plurality of first arcs.

14. The display panel of claim 1, comprising a respective second light emitting element in the second region, and a respective second pixel driving circuit configured to drive light emission in the respective second light emitting element;
wherein the respective second pixel driving circuit is in the third region or in the first region.

15. The display panel of claim 1, comprising a scan circuit having a plurality of stages, and configured to provide control signals to different rows of subpixels;
a respective scan unit of the scan circuit is at least partially in the third region, and is configured to provide scan signals to subpixels in the second region and subpixels in the first region;
the display panel comprises a respective first output line and a respective second output line connected to the respective scan unit;
the respective first output line is configured to transmit control signals from the respective scan unit to a row of subpixels in the first region; and
the respective second output line is configured to transmit control signals from the respective scan unit to a row of subpixels in the third region.

16. The display panel of claim 1, comprising plurality of second data lines configured to provide data signals to subpixels in the second region;
portions of the plurality of second data lines in the second region extend along a plurality of fourth arcs, respectively; and
the plurality of fourth arcs curve toward a same direction.

17. The display panel of claim 1, comprising a main signal line and a plurality of branch signal lines connected to the main signal line, the main signal line and the plurality of branch signal lines configured to provide signals to the subpixels in the second region;
the plurality of branch signal lines form an interconnected signal line network in the second region; and
the main signal line is outside the second region.

18. The display panel of claim 1, wherein the display panel is a curved display panel having a three-dimensional body;
the first region comprises at least a main display region of the display panel;
the second region is at least partially in a corner portion of the three-dimensional body.

19. The display panel of claim 18, wherein the first region includes a first sub-region, a second sub-region, and a third sub-region;
the first sub-region is at least partially in a top portion of the three-dimensional body;
the second sub-region is at least partially in a first edge portion of the three-dimensional body;
the third sub-region is at least partially in a second edge portion of the three-dimensional body; and
the third region at least partially spaces apart the first region and the second region.

20. A display apparatus, comprising the display panel of claim 1, and one or more integrated circuit connected to the display panel.
